(19) United States
(12) Patent Application Publication
(10) Pub. No.: US 2025/0037760 A1
(43) Pub. Date: Jan. 30, 2025

(54) SEMICONDUCTOR STORAGE DEVICE

(71) Applicant: Socionext Inc., Kanagawa (JP)

(72) Inventor: Masanobu HIROSE, Yokohama-shi (JP)

(21) Appl. No.: 18/917,635

(22) Filed: Oct. 16, 2024

Related U.S. Application Data
(63) Continuation of application No. PCT/JP2023/014770, filed on Apr. 11, 2023.

(30) Foreign Application Priority Data
Apr. 20, 2022 (JP) 2022-069503

(51) Int. Cl. G11C 11/419; G11C 11/412; H01L 23/528; H10B 10/00

(52) U.S. Cl. CPC G11C 11/419; G11C 11/412; H01L 23/5286; H10B 10/12

(57) ABSTRACT

Multiple SRAM cells are commonly connected to write-bit lines extending in a Y-direction and a local read-bit line extending in the Y-direction. A local amplifier connected to the local read-bit line outputs a signal received from a selected SRAM cell through the local read-bit line to the global read-bit line. A buried interconnect corresponding to the global read-bit line is formed in a buried interconnect layer. An interconnect corresponding to the local read-bit line is formed in a first interconnect layer.

### CROSS-REFERENCE TO RELATED APPLICATIONS

This is a continuation of International Application No. PCT/JP2023/014770 filed on Apr. 11, 2023, which claims priority to Japanese Patent Application No. 2022-069503 filed on Apr. 20, 2022. The entire disclosures of these applications are incorporated by reference herein.

### BACKGROUND

The present disclosure relates to a semiconductor storage device, and particularly to a layout structure of a 2-port static random access memory (SRAM) cell (hereinafter also simply referred to as a cell as appropriate).

SRAMs have been widely used for semiconductor integrated circuits.

To achieve high integration of a semiconductor integrated circuit, there has been proposed a use of an interconnect provided in a buried interconnect (BI) layer, instead of an interconnect provided in a metal interconnect layer above a transistor as in a traditional case.

R. Mathur et al., “Buried Bitline for sub-5 nm SRAM Design,” 2020 IEEE International Electron Devices Meeting (IEDM), December 2020, IEDM20-409-412 discloses a layout structure of a 1-port SRAM cell with a bit line pair provided in a buried interconnect layer.

### SUMMARY

However, no specific study has been conducted on the layout of a 2-port SRAM cell with the bit lines provided in the buried interconnect layer.

An object of the present disclosure is to provide a layout structure of a 2-port SRAM cell with bit lines provided in a buried interconnect layer.

A first aspect of the present disclosure is directed to a semiconductor storage device including multiple memory arrays. The memory arrays each include multiple 2-port SRAM cells arranged in a first direction. The 2-port SRAM cells in each of the memory arrays are commonly connected to a first write-bit line extending in the first direction, a second write-bit line extending in the first direction and forming a complementary bit line pair together with the first write-bit line, and a local read-bit line extending in the first direction. The local read-bit line is connected to a local amplifier. The local amplifier outputs a signal received from selected one or more of the 2-port SRAM cells to a global read-bit line through the local read-bit line. The global read-bit line includes a first buried interconnect formed in a buried interconnect layer and extending in the first direction in the memory arrays. The local read-bit line includes a first interconnect formed in a first interconnect layer above the buried interconnect layer and extending in the first direction.

Since the first buried interconnect corresponding to the global read-bit line is formed in the buried interconnect layer, there is no need for providing an interconnect corresponding to the global read-bit line in the interconnect layer above the buried interconnect layer. This suppresses an increase in the area of semiconductor storage device. Further, by increasing the film thickness of the first buried interconnect, the resistance of the global read-bit line can be lowered, and the semiconductor storage device can operate at a high speed.

A second aspect of the present disclosure is directed to a semiconductor storage device including multiple memory arrays. The memory arrays each include multiple 2-port SRAM cells arranged side by side in a first direction and in a second direction that is perpendicular to the first direction. The 2-port SRAM cells in each of the memory arrays are commonly connected to a first write-bit line extending in the first direction, a second write-bit line extending in the first direction and forming a complementary bit line pair together with the first write-bit line, and a local read-bit line extending in the first direction. The local read-bit line is connected to a local amplifier. The local amplifier outputs a signal received from selected one or more of the 2-port SRAM cells to a global read-bit line through the local read-bit line. The global read-bit line includes a first buried interconnect formed in a buried interconnect layer, arranged at the boundaries of the SRAM cells arranged in the second direction in the memory arrays, and extending in the first direction.

Since the first buried interconnect corresponding to the global read-bit line is formed in the buried interconnect layer, there is no need for providing an interconnect corresponding to the global read-bit line in the interconnect layer above the buried interconnect layer. This suppresses an increase in the area of semiconductor storage device. Further, by increasing the film thickness of the first buried interconnect, the resistance of the global read-bit line can be lowered, and the semiconductor storage device can operate at a high speed. In addition, since the first interconnect corresponding to the global read-bit lines can be shared by the SRAM cells adjacent in the first direction, the number of global read-bit lines can be reduced.

A third aspect of the present disclosure is directed to a semiconductor storage device including multiple memory arrays. The memory arrays each include multiple 2-port SRAM cells arranged in a first direction. The 2-port SRAM cells in each of the memory arrays are commonly connected to a first write-bit line extending in the first direction, a second write-bit line extending in the first direction and forming a complementary bit line pair together with the first write-bit line, and a local read-bit line extending in the first direction. The local read-bit line is connected to a local amplifier. The local amplifier outputs a signal received from selected one or more of the 2-port SRAM cells to a global read-bit line through the local read-bit line. The local read-bit line includes a first buried interconnect formed in a buried interconnect layer and extending in a first direction. The global read-bit line includes a first interconnect formed in a first interconnect layer above the buried interconnect layer and extending in the first direction in the memory arrays.

Since the first buried interconnect corresponding to the local read-bit line is formed in the buried interconnect layer, there is no need for providing an interconnect corresponding to the local read-bit line in the interconnect layer above the buried interconnect layer. This suppresses an increase in the area of semiconductor storage device. When the interconnect resistance of the buried interconnect layer is high because the sheet resistance of the buried interconnect layer is high and the interconnect thickness cannot be increased, forming local read-bit lines with shorter interconnect lengths than those of the global read-bit lines in the buried interconnect layer can suppress the reduction in the operation speed of the semiconductor storage device.

A fourth aspect of the present disclosure is directed to a semiconductor storage device comprising multiple memory arrays. The memory arrays each include multiple 2-port SRAM cells arranged side by side in a first direction and in a second direction that is perpendicular to the first direction. The 2-port SRAM cells in each of the memory arrays are commonly connected to a first write-bit line extending in the first direction, a second write-bit line extending in the first direction and forming a complementary bit line pair together with the first write-bit line, and a local read-bit line extending in the first direction. The local read-bit line is formed in a buried interconnect layer and is connected to a local amplifier. The local amplifier outputs a signal received from selected one or more of the 2-port SRAM cells to a global read-bit line through the local read-bit line. The global read-bit line is formed in a first interconnect layer above the buried interconnect layer and extends in the first direction to be arranged at the boundaries of the SRAM cells arranged in the second direction in the memory arrays.

Since the first buried interconnect corresponding to the local read-bit line is formed in the buried interconnect layer, there is no need for providing an interconnect corresponding to the local read-bit line in the interconnect layer above the buried interconnect layer. This suppresses an increase in the area of semiconductor storage device. When the interconnect resistance of the buried interconnect layer is high because the sheet resistance of the buried interconnect layer is high and the interconnect thickness cannot be increased, forming local read-bit lines with shorter interconnect lengths than those of the global read-bit lines in the buried interconnect layer can suppress the reduction in the operation speed of the semiconductor storage device. In addition, since the first interconnect corresponding to the global read-bit lines can be shared by the SRAM cells adjacent in the first direction, the number of global read-bit lines can be reduced.

The present disclosure enables achieving of a semiconductor storage device including a 2-port SRAM cell with bit lines provided in a buried interconnect layer.

### BRIEF DESCRIPTION OF THE DRAWINGS

FIG. 1 is a block circuit diagram showing a part of a memory array in a semiconductor storage device of a first embodiment.

FIG. 2 is a block circuit diagram showing the whole memory array in the semiconductor storage device of the first embodiment.

FIG. 3 is a plan view of an exemplary layout structure of a 2-port SRAM cell of the first embodiment.

FIG. 4 is a cross-sectional view of an exemplary layout structure of the 2-port SRAM cell of the first embodiment.

FIG. 5 is a cross-sectional view of an exemplary layout structure of the 2-port SRAM cell of the first embodiment.

FIG. 6 is a circuit diagram showing a configuration of the 2-port SRAM cell of the first embodiment.

FIG. 7 is a plan view of an exemplary layout structure of a driver of a global read-bit line in a local amplifier of the first embodiment.

FIG. 8 is a plan view of another exemplary layout structure of the 2-port SRAM cell of the first embodiment.

FIG. 9 is a plan view of an exemplary layout structure of a 2-port SRAM cell of a second embodiment.

FIG. 10 is a plan view of another exemplary layout structure of the 2-port SRAM cell of a third embodiment.

FIG. 11 is a block circuit diagram showing a part of a memory array in a semiconductor storage device of a fourth embodiment.

FIG. 12 is a block circuit diagram showing the whole memory array in the semiconductor storage device of the fourth embodiment.

FIG. 13 is a plan view of another exemplary layout structure of the 2-port SRAM cell of the fourth embodiment.

FIG. 14 is a block circuit diagram showing a part of a memory array in a semiconductor storage device of a variation of the fourth embodiment.

FIG. 15 is a block circuit diagram showing the whole memory array of the semiconductor storage device of a variation of the fourth embodiment.

FIG. 16 is a plan view of an exemplary layout structure of the 2-port SRAM cell of a fifth embodiment.

FIG. 17 is a plan view of an exemplary layout structure of a driver of a global read-bit line in a local amplifier of the fifth embodiment.

FIG. 18 is a plan view of another exemplary layout structure of the 2-port SRAM cell of the fifth embodiment.

FIG. 19 is a plan view of another exemplary layout structure of the 2-port SRAM cell of the fifth embodiment.

FIG. 20 is a plan view of another exemplary layout structure of the 2-port SRAM cell of the fifth embodiment.

### DETAILED DESCRIPTION

Embodiments will be described in detail with reference to the drawings. The following embodiments assume that a semiconductor storage device includes multiple SRAM cells (in the present specification, hereinafter simply referred to as cells as appropriate) and that at least some of the SRAM cells include, for example, a nanosheet FET. The nanosheet FET is an FET using a thin sheet (nanosheet) through which current flows. The nanosheet is made of silicon, for example.

In the present disclosure, a semiconductor layer portion which is formed at each end of the nanosheet and which forms a terminal serving as the source or drain of the nanosheet FET will be referred to as a “pad.”

In the present disclosure, the SRAM cell includes a buried interconnect (BI) in a buried interconnect layer having an interconnect buried in a substrate or a shallow trench isolation (STI). In the following description, the interconnect provided in the buried interconnect layer may be referred to as a buried interconnect, and particularly, a power rail provided in the buried interconnect layer may be referred to as a buried power rail (BPR).

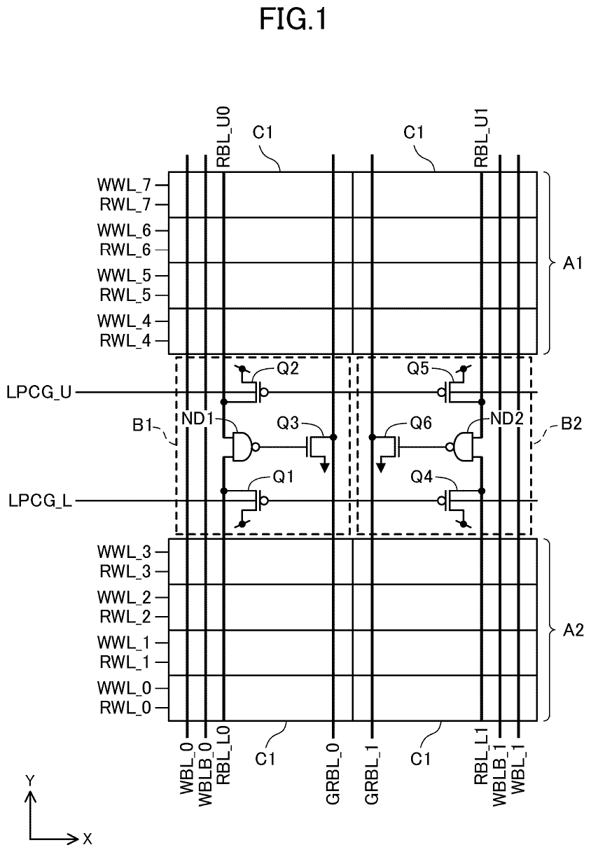

It should be noted that in the following description, the longitudinal direction of the figure in the plan view of FIG. 1 or the like is the Y-direction, the lateral direction is X-direction, and a direction perpendicular to the substrate surface is the Z-direction. The “VDD” represents a power supply voltage, a high voltage power source itself, or a high voltage power line, and the “VSS” represents a power supply voltage, a low voltage power source itself, or a low voltage power line.

In the plan views and sectional views in the embodiments below, insulating films or the like may be omitted. In the plan views and sectional views in the embodiments below, the nanosheet and the pads on both sides thereof may be illustrated in the form of a simplified linear shape. In the present disclosure, the expressions such as “the same size” indicating that the size and the like are the same encompass a range of variation in manufacturing.

In the present disclosure, the source and drain of the transistor will be referred to as “nodes” of the transistor as appropriate. That is, one node of the transistor indicates the source or drain of the transistor, and both nodes of the transistor indicate the source and drain of the transistor.

In the following embodiments and variations thereof, the same reference characters are used to represent equivalent elements, and the description thereof will be omitted.

### First Embodiment

### (Structure in Block Circuit Diagram)

FIG. 1 is a block circuit diagram showing a part of a memory array in a semiconductor storage device of a first embodiment.

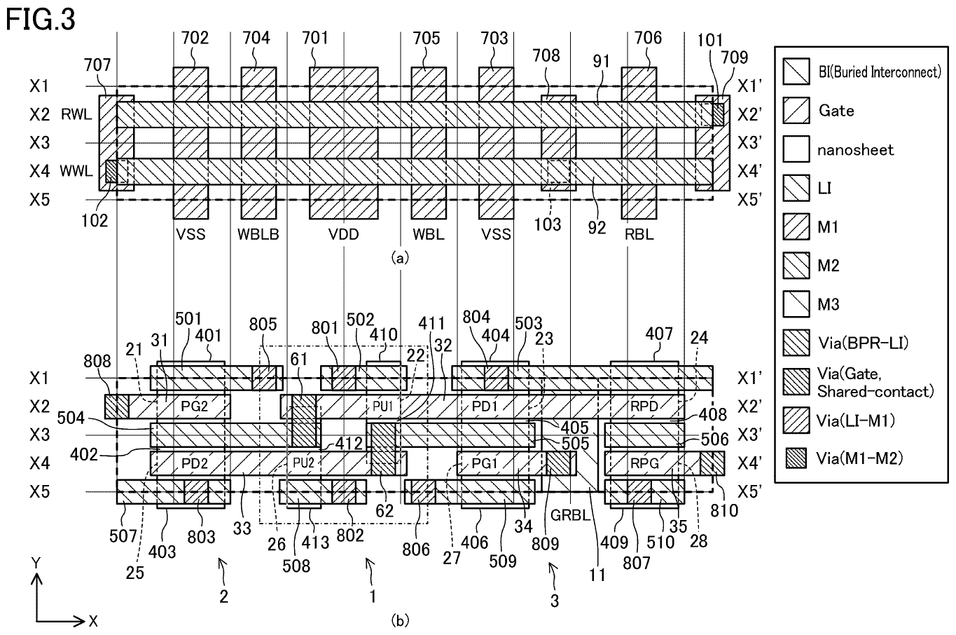

As shown in FIG. 1, a semiconductor storage device of the present embodiment includes memory arrays A1, A2 arranged in the Y-direction. The memory arrays A1, A2 each include multiple SRAM cells C1. In FIG. 1, the memory arrays A1, A2 include two SRAM cells C1 in the X-direction and eight SRAM cells C1 in the Y-direction. In the SRAM cell C1, an SRAM cell of FIG. 3 or the like described later is arranged.

Local amplifiers B1, B2 as reading circuits are arranged between the memory arrays A1, A2. The local amplifiers B1, B2 are arranged to correspond to the columns on the left and right sides of the memory arrays A1, A2 in the drawing, respectively.

As shown in FIG. 1, write-bit lines WBL, WBLB (WBL_0, WBL_1, WBLB_0, and WBLB_1) extending in the Y-direction are formed in the semiconductor storage device of the present embodiment. The write-bit line WBL_0, WBLB_0 are each commonly connected to the SRAM cells C1 arranged in the column on the left side in the memory arrays A1, A2 in the drawing. The write-bit line WBL_1, WBLB_1 are each commonly connected to the SRAM cells C1 arranged in the column on the right side in the memory arrays A1, A2 in the drawing.

Further, local read-bit lines RBL (RBL_U0, RBL_U1, RBL_L0, RBL_L1) extending in the Y-direction are formed in the semiconductor storage device of the present embodiment. The local read-bit lines RBL_U0, RBL_U1 are commonly connected to the SRAM cells C1 arranged in the columns on the left and right sides in the memory array A1 in the drawing. The local read-bit lines RBL_L0, RBL_L1 are commonly connected to the SRAM cells C1 arranged in the columns on the left and right sides in the memory array A2 in the drawing.

Further, write-word lines WWL (WWL_0 to WWL_7) and read-word lines RWL (RWL_0 to RWL_7) extending in the X-direction are formed in the semiconductor storage device of the present embodiment. The write-word lines WWL_0 to WWL_7 are commonly connected to the SRAM cells C1 arranged in the same row. The read-word lines RWL_0 to RWL_7 are commonly connected to the SRAM cells C1 arranged in the same row.

The local amplifier B1 (B2) includes a NAND circuit ND1 (ND2) and transistors Q1 to Q3 (Q4 to Q6). The transistors Q1, Q2, Q4, Q5 are p-type transistors, and the transistors Q3, Q6 are n-type transistors.

The NAND circuit ND1 (ND2) takes the local read-bit lines RBL_U0, RBL_U0 (RBL_U1 and RBL_L1) as inputs.

The transistor Q1 (Q4) has one node connected to the local read-bit line RBL_L0 (RBL_L1) and the other node connected to the power supply voltage VDD and receives the pre-charge control signal LPCG_L at a gate. The transistor Q1 (Q4) pre-charges the local read-bit line RBL_L0 (RBL_L1) to a high level when the pre-charge control signal LPCG_L is at a low level.

The transistor Q2 (Q5) has one node connected to the local read-bit line RBL_U0 (RBL_U1) and the other node connected to the power supply voltage VDD and receives the pre-charge control signal LPCG_U at a gate. The transistor Q2 (Q5) pre-charges the local read-bit line RBL_U0 (RBL_U1) to a high level when the pre-charge control signal LPCG_U is at a low level.

The transistor Q3 (Q6) has one node connected to the power supply voltage VSS, the other node connected to the global read-bit line GRBL_0 (GRBL_1), and a gate connected to an output of the NAND circuit ND1 (ND2).

As shown in FIG. 1, global read-bit lines GRBL (GRBL_0, GRBL_1) extending in the Y-direction are formed in the semiconductor storage device of the present embodiment. In FIG. 1, the global read-bit lines GRBL_0, GRBL_1 are formed to correspond to the columns on the left and the right sides of the memory arrays A1, A2 in the drawing, respectively.

In FIG. 1, in the write operation, data “0” or data “1” is written, through the complementary write-bit lines (WBL_0, WBLB_0, WBL_1, WBLB_1), to the memory cells C1 in the same row selected by the write-word lines WWL (WWL_0 to WWL_7). On the other hand, in the read operation, SRAM cells C1 in the same row arranged in the X-direction are selected by the read-word lines RWL (RWL_0 to RWL_7), and the data is read out to the global read-bit lines (GRBL_0, GRBL_1), through the local read-bit lines RBL (RBL_U0, RBL_U1, RBL_L0, RBL_L1) and local amplifiers (B1, B2).

In a specific read operation, first, each read-word line RWL (RWL_0 to RWL_7) is unselected at the low level and the pre-charge control signals LPCG_U, LPCG_L are at the low level, before the read operation. As a result, each local read-bit line RBL (RBL_U0, RBL_U1, RBL_L0, RBL_L1) is pre-charged to the high level. The global read-bit lines GRBL_0, GRBL_1 are pre-charged to the high level by an I/O control circuit (not shown).

As a result, the output of the NAND circuit ND1 (ND2) drops to the low level and the transistor Q3 (Q6) is turned off, so that the global read-bit line GRBL_0 (GRBL_1) remains at the pre-charged high level.

When the SRAM cell C1 arranged at the lower end of the memory array A2 in the drawing is selected, the pre-charge control signal LPCG_L first rises to the high level, the transistor Q1 (Q4) is turned off, and the pre-charge operation for the local read-bit lines RBL_L0, RBL_L1 is stopped. The read-word line RWL_0 then rises to the high level, and data is read out from memory cell C1 in the same selected column to the local read-bit lines RBL_L0, RBL_L1. On the other hand, in memory array A1, since the pre-charge control signal LPCG_U remains at the low level, transistor Q2 (Q5) remains in the on state, and the pre-charge operation of the local read-bit lines RBL_U0, RBL_U1 continues.

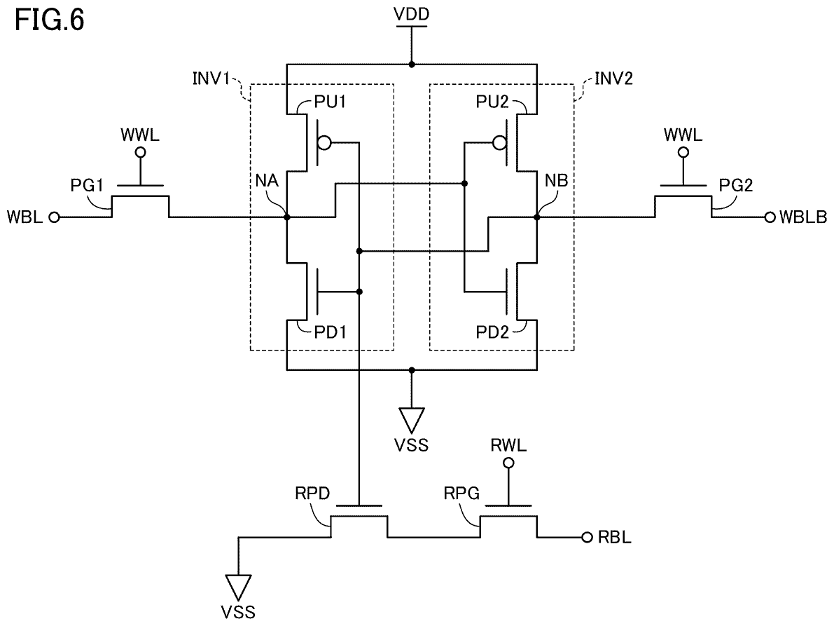

When the retained data of SRAM cell C1 arranged at the lower end of memory array A2 in the drawing is “1”, a node NA of the SRAM cell C1 (the node NA in the later-described circuit diagram in FIG. 6) is at the high level and a node NB (the node NB in the later-described circuit diagram in FIG. 6) drops to the low level. Therefore, the local read-bit line RBL_L0 (RBL_L1) remains at the high level, and the output of the NAND circuit ND1 (ND2) drops to the low level. The transistor Q3 (Q6), at this time, remains in the off state, so that the global read-bit line GRBL_0 (GRBL_1) remains at the high level and data “1” is read from the SRAM cell C1.

On the other hand, when the retained data of SRAM cell C1 arranged at the lower end of memory array A2 in the drawing is “0”, the node NA of the SRAM cell C1 is at the low level and the node NB rises to the high level. Therefore, the local read-bit line RBL_L0 (RBL_L1) drops to the low level, and the output of the NAND circuit ND1 (ND2) rises to the high level. The transistor Q3 (Q6), at this time, turns on, so that the global read-bit line GRBL_0 (GRBL_1) drops to the low level and data “0” is read from the SRAM cell C1.

Similarly, suppose that SRAM cell C1, arranged at the upper end of the memory array A1 in the drawing, is selected. In this case, the read-word line RWL_7 rises to the high level. Then, the pre-charge control signal LPCG_U rises to the high level and the transistor Q2 (Q5) is turned off, so that the pre-charge operation to the local read-bit line RBL_U0 (RBL_U1) stops. On the other hand, in memory array A2, since the pre-charge control signal LPCG_L remains at the low level, the transistor Q1 (Q4) remains in the on state and the pre-charge operation of the local read-bit line RBL_L0 (RBL_L1) continues.

When the retained data of SRAM cell C1 arranged at the upper end of memory array A1 in the drawing is “1” at this time, the node NA of the SRAM cell C1 is at the high level and the node NB drops to the low level. Therefore, the local read-bit line RBL_U0 (RBL_U1) remains at the high level, and the output of the NAND circuit ND1 (ND2) drops to the low level. The transistor Q3 (Q6), at this time, remains in the off state, so that the global read-bit line GRBL_0 (GRBL_1) remains at the high level and data “1” is read from the SRAM cell C1.

On the other hand, when the retained data of SRAM cell C1 arranged at the upper end of memory array A1 in the drawing is “0”, the node NA of the SRAM cell C1 is at the low level and the node NB rises to the high level. Therefore, the local read-bit line RBL_U0 (RBL_U1) drops to the low level, and the output of the NAND circuit ND1 (ND2) rises to the high level. The transistor Q3 (Q6), at this time, turns on, so that the global read-bit line GRBL_0 (GRBL_1) drops to the low level and data “0” is read from the SRAM cell C1.

As described above, the semiconductor storage device of the present embodiment can write and read data to/from the SRAM cell A1 arranged in the memory arrays A1, A2 through the global read-bit line GRBL by controlling the write-bit lines WBL, WBLB, the local read-bit line RBL, the write-word line WWL, and the read-word line RWL.

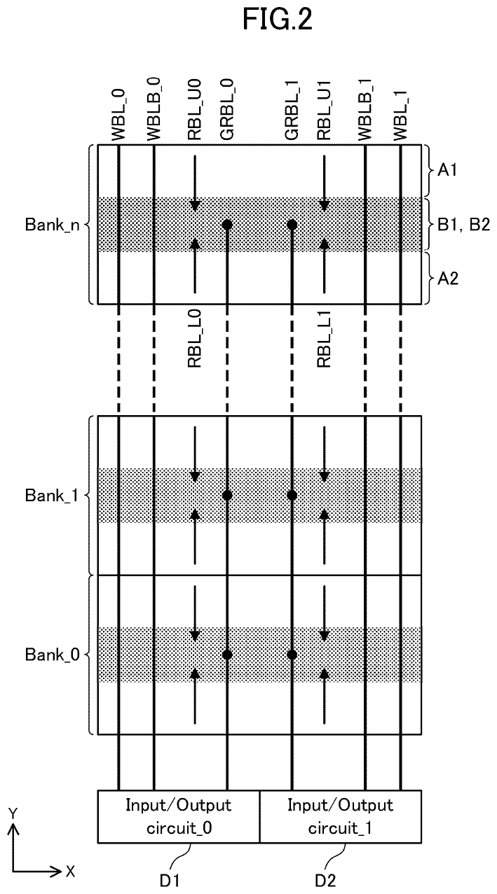

FIG. 2 is a block circuit diagram showing the whole memory array in the semiconductor storage device of the first embodiment.

As shown in FIG. 2, multiple banks (Bank_0 to Bank_n) are formed and aligned in the Y-direction in the semiconductor storage device of the present embodiment. Each of the banks Bank_0 to Bank_n includes a block circuit as shown in FIG. 1.

The write-bit lines WBL, WBLB are commonly connected to each of the banks. Further, the write-bit lines WBL, WBLB are commonly connected to SRAM cell C1 arranged in the same column in each bank.

Specifically, the write-bit lines WBL_0, WBLB_0 are arranged on the left side of the drawing and commonly connected to the banks Bank_0, Bank_1, . . . , Bank_n. The write-bit lines WBL_0, WBLB_0 are commonly connected to the SRAM cells C1 arranged in the column on the left side of the drawing in each bank. Further, the write-bit lines WBL_1, WBLB_1 are arranged on the right side of the drawing and commonly connected to the banks Bank_0, Bank_1, . . . , Bank_n. The write-bit lines WBL_1, WBLB_1 are commonly connected to the SRAM cells C1 arranged in the column on the right side of the drawing in each bank.

The local read-bit lines RBL are arranged independently in each of the banks. Specifically, the local read-bit lines RBL_U0, RBL_U1 are commonly connected to the SRAM cells C1 arranged in the columns on the left and right sides of the memory array A1 in the drawing. The local read-bit lines RBL_L0, RBL_L1 are commonly connected to the SRAM cells C1 arranged in the columns on the left and right sides of the memory array A2 in the drawing.

The transistors Q3 (Q6) in the banks each have one of nodes commonly connected to a global read-bit line GRBL_0 (GRBL_1) extending in the Y-direction.

One input/output (I/O) circuit D1, D2 is formed for each column of SRAM cell C1. The write bit lines WBL_0, WBLB_0 and the global read-bit line GRBL_0 are connected to the input/output circuit D1. The write bit lines WBL_1, WBLB_1 and the global read-bit line GRBL_1 are connected to the input/output circuit D2. The input/output circuit D1 (D2) includes a writing circuit, a reading circuit, and a circuit for pre-charging the global read-bit line GRBL_0 (GRBL_1).

That is, in the semiconductor storage device of the present embodiment, the local amplifier B1 (B2) and the input/output circuit D1 (D2) in each bank are connected through the global read-bit line GRBL_0 (GRBL_1). As a result, 2 bits of data are read out from the two columns of SRAM cells C1 through the global read-bit lines GRBL_0, GRBL_1.

In the bank Bank_n at the upper end of FIG. 2, the global read-bit lines GRBL_0, GRBL_1 do not extend upward beyond the local amplifiers B1, B2. This, however, is for reducing the interconnect load capacitance, and may extend upward beyond the upper part of the local amplifiers B1, B2.

### (Layout Structure of SRAM Cell)

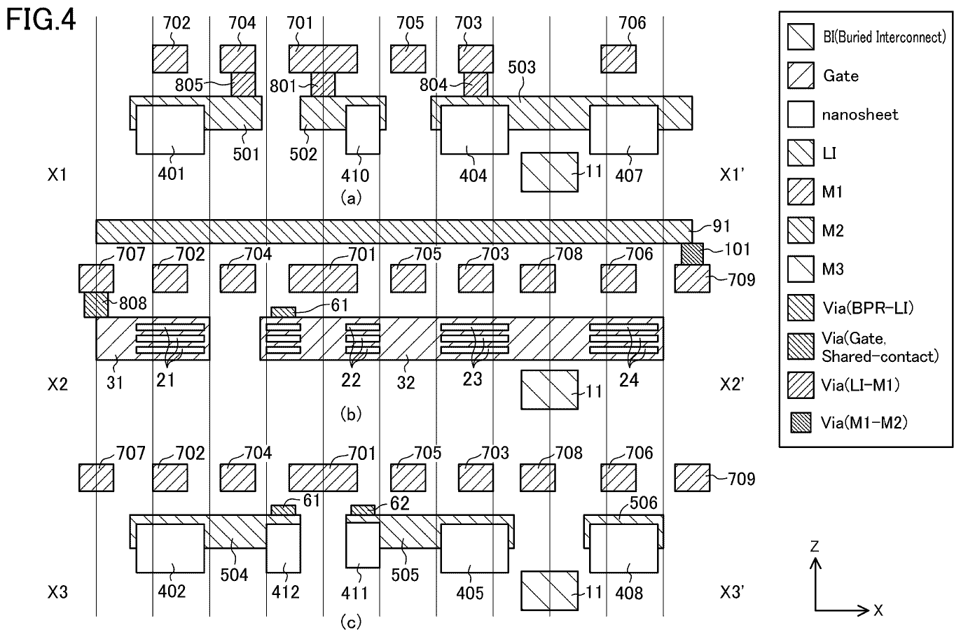

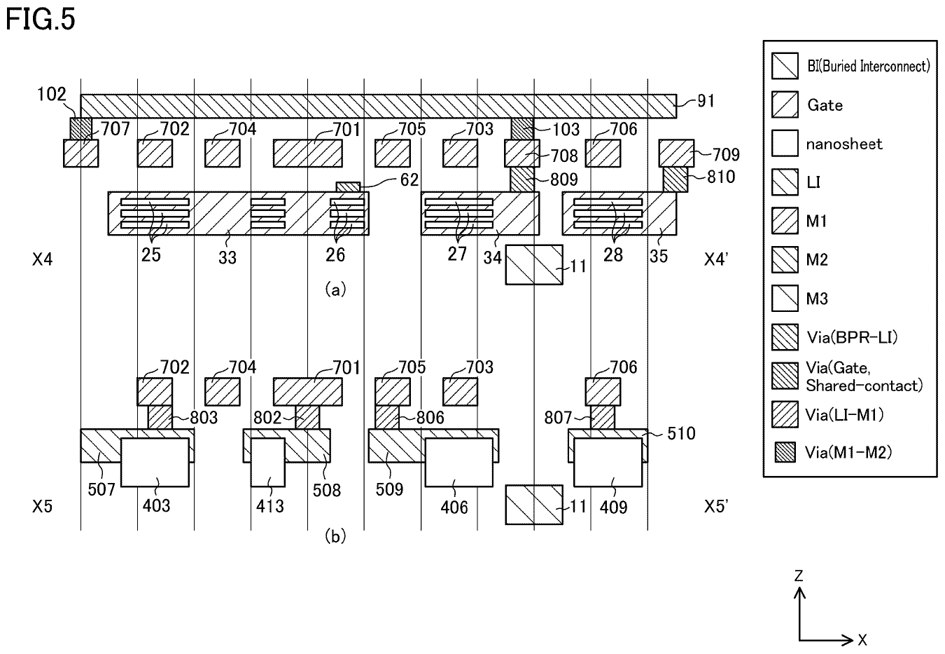

FIG. 3 to FIG. 5 illustrate an exemplary layout structure of a 2-port SRAM cell according to the first embodiment. In FIG. 3, (a) and (b) are plan views, and In FIG. 4 and FIG. 5, (a) to (c) and (a) and (b) are sectional views taken along the lateral direction in plan view. Specifically, in FIG. 3, (a) illustrates a cell upper portion that is M1, M2 interconnect layers, and (b) illustrates a cell lower portion that is a layer below the M1, M2 interconnect layers and includes a nanosheet FET. In FIG. 4, (a) is a cross-section taken along line X1-X1′, (b) is a cross-section taken along line X2-X2′ and (c) is a cross-section taken along line X3-X3′. In FIG. 5, (a) is a cross-section taken along line X4-X4′, (b) is a cross-sectional view taken along line X5-X5′. The 2-port SRAM cells shown in FIG. 3 to FIG. 5 are arranged as the SRAM cell C1 in FIG. 1.

FIG. 6 is a circuit diagram showing a structure of the 2-port SRAM cell of the first embodiment. As shown in FIG. 6, the 2-port SRAM cell includes a 2-port SRAM cell circuit including load transistors PU1, PU2, drive transistors PD1, PD2, access transistors PG1, PG2, a read drive transistor RPD, and a read access transistor RPG. The load transistors PU1, PU2 are P-type FETs, and the drive transistors PD1, PD2, the access transistors PG1, PG2, the read drive transistor RPD, and the read access transistor RPG are N-type FETs.

The load transistor PU1 is provided between the power supply voltage VDD and a first node NA, and the drive transistor PD1 is provided between the first node NA and the power source VSS. The load transistor PU1 and the drive transistor PD1 have their gates connected to a second node NB to form an inverter INV1. The load transistor PU2 is provided between the power supply voltage VDD and the second node NB, and the drive transistor PD2 is provided between the second node NB and the power source VSS. The load transistor PU2 and the drive transistor PD2 have their gates connected to the first node NA to form an inverter INV2. That is, the output of one inverter is connected to the input of the other inverter, whereby a latch is formed.

The access transistor PG1 is provided between a write-bit line WBL and the first node NA, and has a gate connected to a write-word line WWL. The access transistor PG2 is provided between a write-bit line WBLB and the second node NB, and has a gate connected to a write-word line WWL. The write-bit lines WBL, WBLB form a complementary write-bit line pair.

The read drive transistor RPD has a source connected to the power source VSS, a gate connected to the second node NB, and a drain connected to the source of the read access transistor RPG. The read access transistor RPG has a gate connected to a read-word line RWL and a drain connected to a local read-bit line RBL.

In the SRAM cell circuit of FIG. 6, when the write-bit lines WBL, WBLB forming the complementary write-bit line pair are driven to a high level and a low level, respectively, to drive the write-word line WWL to the high level, the high level is be written to the first node NA and the low level is written to the second node NB. On the other hand, when the write-bit lines WBL, WBLB are driven to the low level and the high level, respectively, to drive the write-word line WWL to the high level, the low level is written to the first node NA and the high level is written to the second node NB. Then, when the write-word line WWL is driven to the low level with the data written to the first and the second nodes NA, NB, a latch state is determined and the data written to the first and the second nodes NA, NB is retained.

Further, with the local read-bit line RBL pre-charged in advance to the high level, driving the read-word line RWL to the high level determines the state of the local read-bit line RBL according to the data written to the second node NB, and data can be read out from the SRAM cell. Specifically, when the second node NB is at the high level, the local read-bit line RBL is discharged to the low level. On the other hand, when the second node NB is at the low level, the local read-bit line RBL remains the high level.

As described above, the 2-port SRAM cell has a function of writing and retaining data to and in the 2-port SRAM cell and reading out data from the 2-port SRAM cell by controlling the write-bit lines WBL, WBLB, the local read-bit line RBL, the write-word line WWL, and the read-word line RWL.

In the following description, solid lines running longitudinally and laterally in the plan view of FIG. 3 and solid lines running longitudinally in the cross-sectional view of FIG. 4 and the like illustrate a grid used for arranging components at the time of designing. Cells of the grid are arranged at equal intervals in the X-direction, and are arranged at equal intervals in the Y-direction. The intervals of the cells of the grid in the X-direction and those in the Y-direction may be the same or different. The intervals of the cells of the grid may be different among layers. Further, each component is not necessarily disposed on the grid. For the sake of reduction in manufacturing variations, each component is preferably disposed on the grid.

Dotted lines surrounding the cell in, e.g., the plan view of FIG. 3 indicate a cell frame of the SRAM cell (outer edge of the SRAM cell). The SRAM cell is disposed such that its cell frame comes into contact with a cell frame of an adjacent cell in the X-direction or the Y-direction.

In, e.g., the plan view of FIG. 3, the SRAM cells inverted in the X-direction are arranged on both sides of the SRAM cell in the X-direction. The SRAM cells inverted in the Y-direction are arranged on both sides of the SRAM cell in the Y-direction.

As shown in (b) of FIG. 3, a buried interconnect 11 extending in the Y-direction is formed in the buried interconnect layer, spanning both the upper and the lower ends of the cell in the drawing. Specifically, the buried interconnect 11 is formed between the nanosheet 23 (27) and the nanosheet 24 (28) (described later) in plan view. The buried interconnect 11 corresponds to the global read-bit line GRBL. The buried interconnect 11 is not connected to another interconnect or the like in the SRAM cell, but is connected to the local amplifier B1 (B2) in the bank as described above. The buried interconnect 11 does not have to be formed in advance. An interconnect area may be provided in advance and the buried interconnect 11 may be formed only in a necessary area when designing semiconductor storage devices.

The load transistors PU1, PU2 are formed on an N-well 1. The access transistor PG2 and the drive transistor PD2 are formed on a P-type substrate 2. The drive transistor PD1, the access transistor PG1, the read drive transistor RPD, and the read access transistor RPG are formed on a P-type substrate 3.

As shown in (b) of FIG. 3, nanosheets 21 to 28 extending in the X-direction and the Y-direction are formed. The nanosheets 21 to 24 are arranged in the X-direction in the order of the nanosheets 21 to 24. The nanosheets 25 to 28 are arranged in the X-direction in the order of the nanosheets 25 to 28. The nanosheets 21, 25 are formed and aligned in the Y-direction. The nanosheets 23, 27 are formed and aligned in the Y-direction. The nanosheets 24, 28 are formed and aligned in the Y-direction. The width of the nanosheet 21, 23, 24, 25, 27, 28 in the X-direction is twice the width of the nanosheet 22, 26 in the X-direction.

The nanosheets 21 to 28 form channel portions of the access transistor PG2, the load transistor PU1, the drive transistor PD1, the read drive transistor RPD, the drive transistor PD2, the load transistor PU2, the access transistor PG1, and the read access transistor RPG, respectively.

As shown in (b) of FIG. 4 and (a) of FIG. 5, the nanosheets 21 to 28 are each constituted by three semiconductor sheets (nanosheets). Each of the nanosheets 21 to 28 is arranged such that the nanosheets forming each of the nanosheets 21 to 28 overlap each other in plan view and are separated from each other in the Z-direction. That is, the nanosheet FET in the 2-port SRAM cell of the present embodiment includes three nanosheets.

As shown in (b) of FIG. 3, gate interconnects (Gate) 31 to 35 extend in the X-direction and the Z-direction. The gate interconnects 31, 32 are arranged in the X-direction, and the gate interconnects 33 to 35 are arranged in the X-direction.

The gate interconnect 31 overlaps the nanosheet 21 in plan view. The gate interconnect 32 overlaps the nanosheets 22 to 24 in plan view. The gate interconnect 33 overlaps the nanosheets 25, 26 in plan view. The gate interconnect 34 overlaps the nanosheet 27 in plan view. The gate interconnect 35 overlaps the nanosheet 28 in plan view.

The gate interconnect 31 serves as the gate of the access transistor PG2. The gate interconnect 32 serves as the gates of the load transistor PU1, the drive transistor PD1, and the read drive transistor RPD. The gate interconnect 33 serves as the gates of the drive transistor PD2 and the load transistor PU2. The gate interconnect 34 serves as the gate of the access transistor PG1. The gate interconnect 35 serves as the gate of the read access transistor RPG.

Pads 401 to 409 doped with an N-type semiconductor are formed at the upper end of the nanosheet 21 in the drawing, between the nanosheets 21, 25, at the lower end of the nanosheet 25 in the drawing, at the upper end of the nanosheet 23 in the drawing, between the nanosheets 23, 27, at the lower end of the nanosheet 27 in the drawing, at the upper end of the nanosheet 24 in the drawing, between the nanosheets 24, 28, and at the lower end of the nanosheet 28 in the drawing, respectively. The pads 401, 402 form the node of the access transistor PG2. The pads 402, 403 form the node of the drive transistor PD2. The pads 404, 405 form the node of the drive transistor PD1. The pads 405, 406 form the node of the access transistor PG1. The pads 407, 408 form the node of the read drive transistor RPD. The pads 408, 409 form the node of the read access transistor RPG.

Pads 410 to 413 doped with a P-type semiconductor are formed at the upper end of the nanosheet 22 in the drawing, the lower end of the nanosheet 22 in the drawing, the upper end of the nanosheet 26 in the drawing, and the lower end of the nanosheet 26 in the drawing, respectively. The pads 410, 411 form the node of the load transistor PU1. The pads 412, 413 form the node of the load transistor PU2.

In a local interconnect layer, local interconnects (LIs) 501 to 510 extending in the X-direction are formed. The local interconnect 501 is connected to the pad 401. The local interconnect 502 is connected to the pad 410. The local interconnect 503 is connected to the pads 404, 407. The local interconnect 504 is connected to the pads 402, 412. The local interconnect 505 is connected to the pads 405, 411. The local interconnect 506 is connected to the pad 408. The local interconnect 507 is connected to the pad 403. The local interconnect 508 is connected to the pad 413. The local interconnect 509 is connected to the pad 406. The local interconnect 510 is connected to the pad 409.

The local interconnect 504 is connected to the gate interconnect 32 through a shared-contact 61. The local interconnect 505 is connected to the gate interconnect 33 through a shared-contact 62. The gate interconnect 33, the local interconnect 505, and the shared-contact 62 correspond to the first node NA. The gate interconnect 32, the local interconnect 504, and the shared-contact 61 correspond to the second node NB.

As shown in (a) in FIG. 3, in the M1 interconnect layer, interconnects 701 to 706 extending in the Y-direction are formed, spanning both the upper and the lower ends of the cell in the drawing. In addition, interconnects 707 to 709 are formed. The interconnect 701 supplies the power supply voltage VDD. The interconnects 702, 703 supply the power supply voltage VSS. The interconnects 704 to 706 correspond to the write-bit lines WBLB, WBL and the local read-bit line RBL, respectively.

The interconnect 701 is connected to the local interconnect 502 through a contact (Via) 801, and connected to the local interconnect 508 through a contact 802. The interconnect 702 is connected to the local interconnect 507 through a contact 803. The interconnect 703 is connected to the local interconnect 503 through a contact 804. The interconnect 704 is connected to the local interconnect 501 through a contact 805. The interconnect 705 is connected to the local interconnect 509 through a contact 806. The interconnect 706 is connected to the local interconnect 510 through a contact 807. The interconnect 707 is connected to the gate interconnect 31 through a contact (Gate-contact) 808. The interconnect 708 is connected to the gate interconnect 34 through a contact 809. The interconnect 709 is connected to the gate interconnect 35 through a contact 810.

Interconnects 91, 92 extending in the X-direction, spanning both the left and right ends of the cell in the drawing, are formed in the M2 interconnect layer above the M1 interconnect layer. The interconnects 91, 92 correspond to the read-word line RWL and the write-word line WWL, respectively. The interconnect 91 is connected to the interconnect 709 through a contact 101. The interconnect 92 is connected to the interconnect 707 through a contact 102, and is connected to the interconnect 708 through a contact 103.

With the above configuration, memory arrays A1, A2 include multiple SRAM cells C1 (2-port SRAM cells) arranged in the X-direction and Y-direction, respectively. The SRAM cells C1 arranged in the Y-direction are commonly connected to the write-bit lines WBL, WBLB extending in the Y-direction and the local read-bit line RBL extending in the Y-direction. The local read-bit line RBL is connected to the local amplifier B1 (B2). The local amplifier B1 (B2) outputs the signal received from the selected SRAM cell C1 through the local read-bit line RBL to the global read-bit line GRBL. The buried interconnect 11 corresponding to the global read-bit line GRBL is formed in the buried interconnect layer. The interconnect 706 corresponding to the local read-bit line RBL is formed in the M1 interconnect layer.

In the absence of the buried interconnect layer, the global read-bit lines needed to use the M3 interconnect layer, which is further above the M2 interconnect layer, for the sake of the cell area downsizing and the read speed. On the other hand, since the present embodiment has the buried interconnect 11 corresponding to the global read-bit line GRBL formed in the buried interconnect layer, there is no need for providing an interconnect corresponding to the global read-bit line GRBL in the M3 interconnect layer. This suppresses an increase in the area of semiconductor storage device and enables reduction of the number of interconnect layers.

Further, since the global read-bit line GRBL (buried interconnect 11), extending in the Y-direction across the most of the semiconductor storage device, is provided in the buried interconnect layer, increasing the film thickness (length in the Z-direction) of the buried interconnect 11 allows reduction in the resistance of the global read-bit line GRBL, thereby allowing a high speed operation of the semiconductor storage device.

Further, since no other interconnects (especially local read-bit line RBL) is formed in the buried interconnect layer where the buried interconnect 11 corresponding to the global read-bit line GRBL is formed, the interconnect capacitance can be reduced, thereby allowing a high speed operation of the semiconductor storage device.

### (Layout Structure of Local Amplifier)

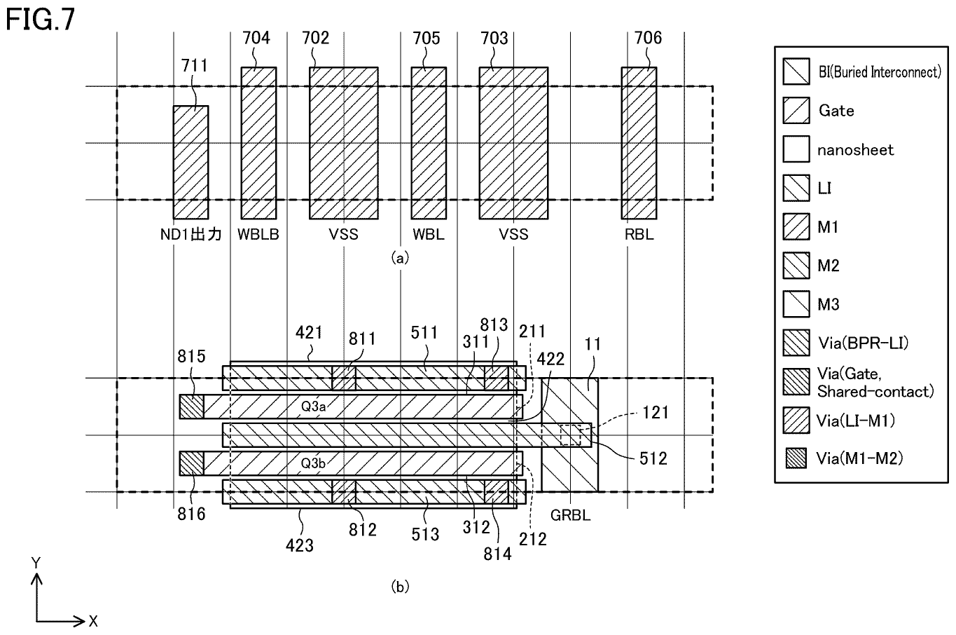

In FIG. 7, (a) and (b) are plan views showing an exemplary layout structure of a driver of a global read-bit line in a local amplifier of the first embodiment. Specifically, in FIG. 7, (a) shows an upper portion of the driver, and (b) shows a lower portion of the driver. FIG. 7 shows a layout structure of the transistor Q3 in FIG. 1. As described above, the local amplifier includes the NAND circuit ND1 and the transistors Q1, Q2 in addition to the transistor Q3, but these are omitted in the illustration of FIG. 7. In FIG. 7, the transistor Q3 is formed by two transistors (transistors Q3a, Q3b).

As shown in (b) in FIG. 7, the buried interconnect 11 (global read-bit line GRBL) extending in the Y-direction, spanning both the upper and the lower ends of the drawing, is formed in the buried interconnect layer.

Further, nanosheets 211, 212 extending in the X-direction and Y-direction are formed and aligned in the Y-direction. The nanosheet 211, 212 constitutes a channel portion of the transistors Q3a, Q3b.

Gate interconnects 311, 312 extending in the X-direction and Z-direction are formed and aligned in the Y-direction. The gate interconnects 311, 312 overlaps the nanosheet 211, 212 in a plan view, respectively. The gate interconnects 311, 312 serve as gates of the transistors Q3a, Q3b, respectively.

Pads 421 to 423 doped with an N-type semiconductor are formed at the upper end of the nanosheet 211 in the drawing; between the nanosheets 211, 212; and at the lower end of the nanosheet 212 in the drawing, respectively. Pads 421, 422 constitute a node of the transistor Q3a. Pads 422, 423 constitutes a node of the transistor Q3b.

In the local interconnect layer, local interconnects 511 to 513 extending in the X-direction are formed. The local interconnects 511 to 513 are connected to the pads 421 to 423, respectively. The local interconnect 512 is connected to the buried interconnect 11 through a contact 121.

As shown in (a) in FIG. 7, in the M1 interconnect layer, the interconnects 702 to 706 extending in the Y-direction are formed, spanning both the upper and the lower ends of the drawing. Further, an interconnect 711 is formed. The interconnect 711 is an interconnect connected to the output of the NAND circuit ND1.

The interconnect 702 is connected to the local interconnect 511 through a contact 811, and connected to the local interconnect 513 through a contact 812. The interconnect 703 is connected to the local interconnect 511 through a contact 813, and connected to the local interconnect 513 through a contact 814. The interconnect 711 is connected to a gate interconnect 311 through a contact 815, and is connected to a gate interconnect 312 through a contact 816.

As shown in (a) in FIG. 7, interconnects 704, 705 corresponding to the write-bit lines WBLB, WBL, respectively, are formed in the M1 interconnect layer. The interconnects 704, 705 are not connected to other interconnects in the local amplifier B1 (B2), but are connected to the interconnects 704, 705 in the SRAM cell C1 (SRAM cell in FIG. 3 or the like), respectively.

As shown in (b) in FIG. 7, the buried interconnect 11 corresponding to the global read-bit line GRBL is formed in the buried interconnect layer. The buried interconnect 11 is connected to the transistor Q3 (Q3a, Q3b) in the local amplifier through the local interconnect 513 and the contact 121, and is connected to the buried interconnect 11 in the SRAM cell C1. That is, the buried interconnect 11 is connected to the transistor Q3 without going through an upper interconnect layer such as the M1 interconnect layer. This allows reduction in the resistance of the global read-bit line GRBL, allows a high speed operation of the semiconductor storage device, and improves the degree of freedom in designing of the upper interconnect layer in the local amplifier section.

### Variations

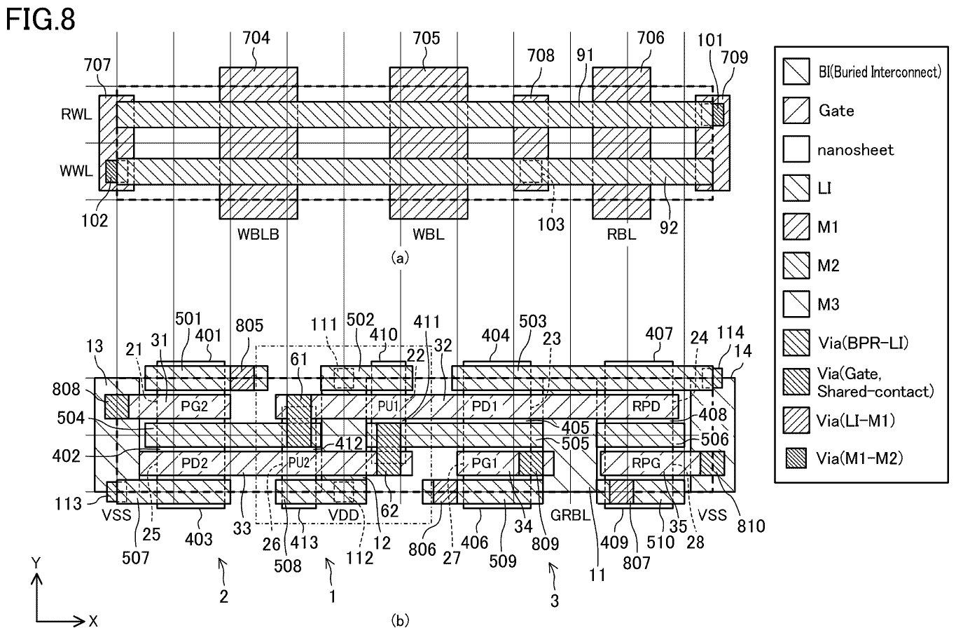

In FIG. 8, (a) and (b) are plan views of another exemplary layout structure of the 2-port SRAM cell according to the first embodiment. Specifically, in FIG. 8, (a) shows a cell upper portion, and (b) shows a cell lower portion. When compared with FIG. 3, FIG. 8 shows a case where the interconnects 701 to 703 of the M1 interconnect layer are omitted and the buried power rails 12 to 14 are formed in the buried interconnect layer.

As shown in (b) in FIG. 8, the buried power rails 12 to 14 extending in the Y-direction are formed in the buried interconnect layer, spanning both the upper and the lower ends of the cell in the drawing. The buried power rail 12 supplies a power supply voltage VDD. The buried power rails 13, 14 supply a power supply voltage VSS. The buried power rail 12 is formed at the center of the cell in the drawing. The buried power rail 13, 14 is formed at each of cell boundaries at both left and right ends of the cell in the drawing. The buried power rails 13, 14 are shared with 2-port SRAM cells arranged on the left and right sides of the 2-port SRAM cell in the drawing.

The buried power rail 12 is connected to a local interconnect 502 through a contact 111, and is connected to a local interconnect 508 through a contact 112. The buried power rail 13 is connected to the local interconnect 507 through a contact 113. The buried power rail 14 is connected to a local interconnect 503 through a contact 114.

As shown in (a) in FIG. 8, in the M1 interconnect layer, interconnects 704 to 706 extending in the Y-direction are formed, spanning both the upper and the lower ends of the cell in the drawing. The interconnects 704, 705 each have interconnect width greater than that of the buried interconnect 11 and those of the buried power rails 12 to 14 in plan view.

In this variation, since the buried power rail 12 that supplies the power supply voltage VDD and the buried power rails 13, 14 that supply the power supply voltage VSS are formed in the buried interconnect layer, the interconnect width of the interconnects 704, 705 corresponding to the respective write-bit lines WBLB, WBL can be increased. This makes it possible to improve the write characteristics of the semiconductor storage device, such as a higher speed and a lower voltage. Further, since the interconnect width of the interconnect 706 corresponding to the local read-bit line RBL can be increased, the read speed to the local read-bit line RBL can be improved, and the read speed from the local read-bit line RBL to the global read-bit line GRBL can be improved. Thus, the read characteristics can be improved in the entire read path of the semiconductor storage device.

Further, since the buried power rail 12 that supplies the power supply voltage VDD and the buried power rails 13, 14 that supply the power supply voltage VSS are formed in the buried interconnect layer, the degree of freedom in designing the M1 interconnect layer is improved.

In FIG. 8, the buried power rail 12 that supplies the power supply voltage VDD and the buried power rails 13, 14 that supply the power supply voltage VSS are formed in the buried interconnect layer, but the present invention is not limited to this, and a part of the buried power rails 12 to 14 may be formed in the M1 interconnect layer.

### Second Embodiment

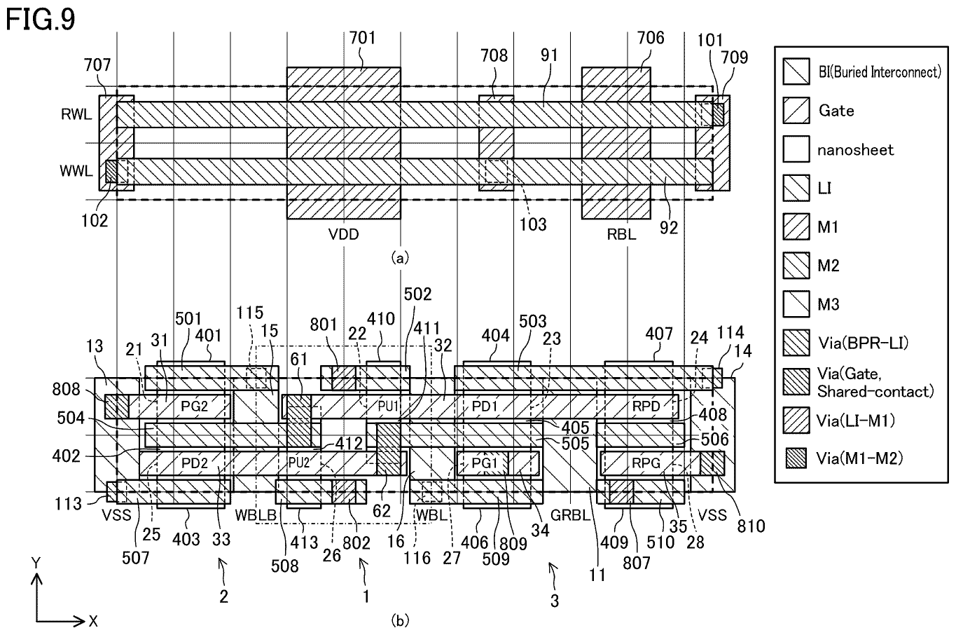

In FIG. 9, (a) and (b) are plan views of an exemplary layout structure of a 2-port SRAM cell according to a second embodiment. Specifically, in FIG. 9, (a) shows a cell upper portion, and (b) shows a cell lower portion. When compared with FIG. 3, FIG. 9 shows a case where the interconnects 702 to 705 of the M1 interconnect layer are omitted and the buried power rails 13, 14 and the buried interconnects 15, 16 are formed in the buried interconnect layer.

As shown in (b) in FIG. 9, in the buried interconnect layer, buried power rails 13, 14 and buried interconnects 15, 16 extending in the Y-direction are formed, spanning both the upper and the lower ends of the cell in the drawing. The buried power rails 13, 14 supply a power supply voltage VSS. The buried power rail 13, 14 is formed at each of cell boundaries at both left and right ends of the cell in the drawing. The buried power rails 13, 14 are shared with 2-port SRAM cells arranged on the left and right sides of the 2-port SRAM cell in the drawing. The buried interconnects 15, 16 correspond to the write-bit lines WBLB, WBL, respectively.

The buried power rail 13 is connected to the local interconnect 507 through a contact 113. The buried power rail 14 is connected to a local interconnect 503 through a contact 114. The buried interconnect 15 is connected to the local interconnect 501 through the contact 115. The buried interconnect 16 is connected to the local interconnect 509 through the contact 116.

As shown in (a) in FIG. 9, in the M1 interconnect layer, interconnects 701, 706 extending in the Y-direction are formed, spanning both the upper and the lower ends of the cell in the drawing. The interconnects 701, 706 each have interconnect width greater than those of buried interconnect 11, 15, 16 and those of the buried power rails 13, 14 in plan view.

In the layout structure shown in FIG. 9, the buried interconnects 15, 16 corresponding to the write-bit lines WBLB, WBL, respectively, are formed in the buried interconnect layer. Therefore, there is no need for providing interconnects corresponding to the write-bit lines WBLB, WBL in the M1 interconnect layer. This suppresses an increase in the area of the semiconductor storage device.

Further, increasing the film thickness (length in the Z-direction) of the buried interconnects 15, 16 reduces the resistance of the write-bit lines WBLB, WBL, respectively, which allows improvement in the write characteristics such as a higher speed and a lower voltage of the semiconductor storage device.

In FIG. 9, the buried power rails 13, 14 that supply the power supply voltage VSS are formed in the buried interconnect layer, but the present invention is not limited to this, and the interconnect that supplies the power supply voltage VSS may be formed in the M1 interconnect layer.

### Third Embodiment

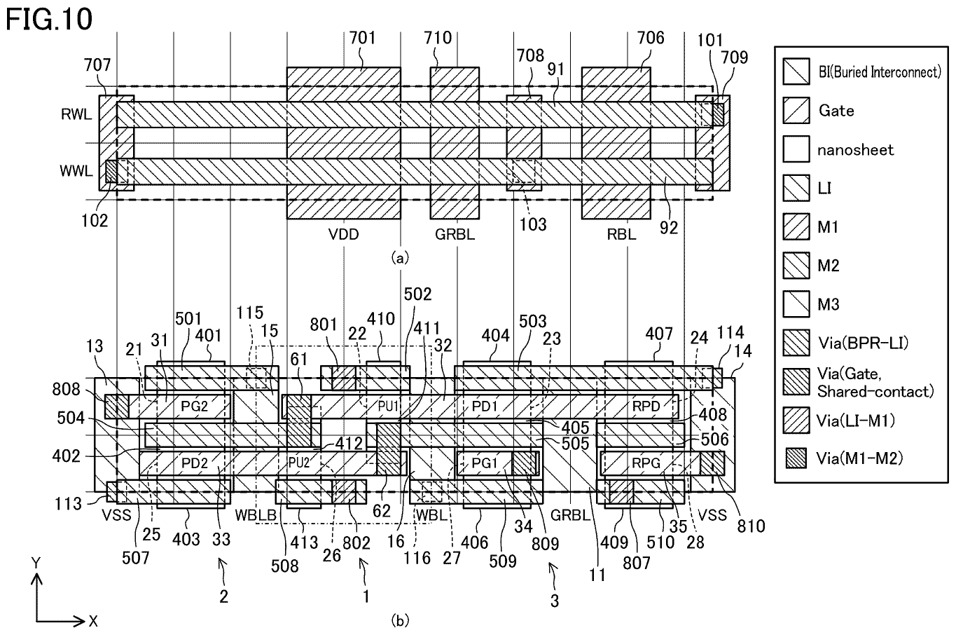

In FIG. 10, (a) and (b) are plan views of an exemplary layout structure of a 2-port SRAM cell according to a third embodiment. Specifically, in FIG. 10, (a) shows a cell upper portion, and (b) shows a cell lower portion. When compared with FIG. 9, FIG. 10 shows a case where an interconnect 710 is formed in the M1 interconnect layer.

As shown in (a) in FIG. 10, in the M1 interconnect layer, interconnect 710 extending in the Y-direction are formed, spanning both the upper and the lower ends of the cell in the drawing. The interconnect 710 corresponds to the global read-bit line GRBL. Similarly to the buried interconnect 11, the interconnect 710 is not connected to another interconnect or the like in the SRAM cell, but is connected to the local amplifier B1 (B2) in the bank as described above. The interconnect 710 does not have to be formed in advance. An interconnect area may be provided in advance and the buried interconnect 710 may be formed only in a necessary area when designing semiconductor storage devices.

The interconnect 710 does not overlap the buried interconnect 11 in a plan view. Further, the interconnect 708 is arranged between the interconnects 706, 710.

The buried interconnect 11 formed in the buried interconnect layer and the interconnect 710 formed in the M1 interconnect layer are commonly connected in an area other than the area where the 2-port SRAM cell is arranged, for example, connected in the area where the local amplifiers B1, B2 are arranged, or the input/output circuits D1, D2 are arranged.

In the layout structure of FIG. 10, the global read-bit line GRBL includes buried interconnect 11 formed in the buried interconnect layer and interconnect 710 formed in the M1 interconnect layer. That is, two global read-bit lines GRBL are formed in the SRAM cell. This way, the resistance of the global read-bit line GRBL can be lowered, and the semiconductor storage device can operate at a high speed.

Further, although the buried interconnect 11 of the buried interconnect layer needs to be arranged in the area where no transistor is formed in the SRAM cell, the interconnect 710 of the M1 interconnect layer can be arranged regardless of the arrangement of the transistors in the SRAM cell. This makes it possible to improve the degree of freedom in designing the semiconductor storage device.

Further, the interconnect 708 is arranged between the interconnects 706, 710. Thus, crosstalk noise between the local read-bit line RBL and the global read-bit line GRBL can be suppressed so that the semiconductor storage device can be stably operated at a high speed.

Although the interconnect 701 that supplies the power supply voltage VDD is formed in the M1 interconnect layer in FIG. 10, the present invention is not limited to this, and the interconnect that supplies the power supply voltage VDD may be formed in the buried interconnect layer.

### Fourth Embodiment

### (Structure in Block Circuit Diagram)

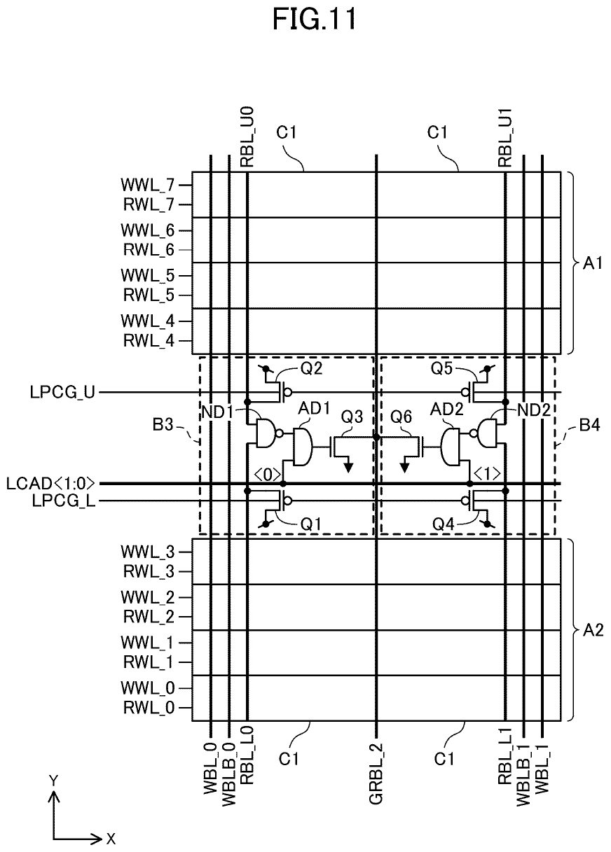

FIG. 11 is a block circuit diagram showing a part of a memory array in a semiconductor storage device of the fourth embodiment. When compared with FIG. 1, FIG. 11 shows a semiconductor storage device including only one global read-bit line GRBL (GRBL_2) and local amplifiers B3, B4 arranged instead of the local amplifiers B1, B2.

As shown in FIG. 11, one global read-bit line GRBL (GRBL_2) is formed at the boundary between two SRAM cells C1 aligned in the X-direction. The global read-bit line GRBL_2 is shared by the SRAM cells C1 arranged in the X-direction.

The local amplifiers B3 and B4 include AND circuits AD1 and AD2, respectively. The AND circuit AD1 (AD2) has one input connected to the output of the NAND circuit ND1 (ND2), another input configured to receive the column selection signal LCAD<0> (LCAD<1>), and the output connected to the gate of the transistor Q3 (Q6).

In FIG. 11, data of the SRAM cells C1 in the same row selected by the read-word lines RWL (RWL_0 to RWL_7) is input to the local amplifier B3 (B4) through the local read-bit lines RBL (RBL_U0, RBL_U1, RBL_L0, RBL_L1). Further, in FIG. 11, data is selectively read out to the global read-bit line GRBL_2 through the transistor Q3 or the transistor Q6, according to the states of the column selection signal LCAD<1:0> and the output signals of the AND circuits AD1 and AD2 that take the outputs of NAND circuits ND1 and ND2 as inputs.

Specifically, the column selection signal LCAD selects the column of SRAM cells C1 on the left side of the drawing or the column of SRAM cells C1 on the right side of the drawing. In FIG. 11, the column selection signal LCAD<0> is input to the AND circuit AD1 of the local amplifier B3, and the column selection signal LCAD<1> is input to the AND circuit AD2 of the local amplifier B4. One of the column selection signals LCAD<0> and LCAD<1> is set to the high level, and the other is set to the low level. It is supposed here that the SRAM cell C1 arranged at the lower left end of the memory array A2 in the drawing is selected. In this case, the column selection signal LCAD<0> rises to the high level, and the column selection signal LCAD<1> drops to the low level.

When the data of the SRAM cell C1 at the lower left end of the memory array A2 in the drawing is read out, while the retained data of the SRAM cell C1 at the lower left end of the memory array A2 in the drawing is “1” and the retained data of the SRAM cell C1 at the lower right end of the memory array A2 in the drawing is “0”, the global read-bit line GRBL_2 rises to the high level by the pre-charge operation, and both local read-bit lines RBL_L0 and RBL_L1 rise to the high level. After the local read-bit line pre-charge control signal LPCG_L is set to the high level to cancel the pre-charge operation, the data of the selected SRAM cell is read out to the local read-bit line RBL when the read-word line RWL_0 is set to the high level. Here, the local read-bit line RBL_L0 remains at the high level, and the local read-bit line RBL_L1 transitions to a low level. On the other hand, since the memory array A1 side is unselected, the local bit line pre-charge control signal LPCG_U remains at the low level and maintains the pre-charge state, and the local read-bit lines RBL_U0 and RBL_U1 remain at the high level. Therefore, the output of the NAND circuit ND1 drops to the low level, and the output of the NAND circuit ND2 rises to the high level. Further, the column selection signal LCAD<0> is set to the high level and LCAD<1> to the low level, and the output of AND circuit AD1 drops to the low level and the output of AND circuit AD2 also drops to the low level. Thus, since the transistors Q3, Q6 are both in the off state, the global read-bit line GRBL_2 remains at the high level, and the retained data “1” of the SRAM cell C1 at the lower left end of memory array A2 in the drawing can be read out.

Meanwhile, when the data of the SRAM cell C1 at the lower left end of the memory array A2 in the drawing is read out, while the retained data of the SRAM cell C1 at the lower left end of the memory array A2 in the drawing is “0” and the retained data of the SRAM cell C1 at the lower right end of the memory array A2 in the drawing is “1”, the global read-bit line GRBL_2 rises to the high level by the pre-charge operation, and both local read-bit lines RBL_L0 and RBL_L1 rise to the high level. After the local read-bit line pre-charge control signal LPCG_L is set to the high level to cancel the pre-charge operation, the data of the selected SRAM cell is read out to the local read-bit line RBL when the read-word line RWL_0 is set to the high level. Here, the local read-bit line RBL_L0 transitions to the low level, and the local read-bit line RBL_L1 remains at the high level. On the other hand, since the memory array A1 side is unselected, the local bit line pre-charge control signal LPCG_U remains at the low level and maintains the pre-charge state, and the local read-bit lines RBL_U0 and RBL_U1 remain at the high level. Therefore, the output of the NAND circuit ND1 rises to the high level, and the output of the NAND circuit ND2 drops to the low level. Further, the column selection signal LCAD<0> is set to the high level and LCAD<1> to the low level, and the output of AND circuit AD1 rises to the high level and the output of AND circuit AD2 is also at the low level. Therefore, since the transistor Q3 is in the on state and the transistor Q6 is in the off state, the global read-bit line GRBL_2 transitions to the low level, and the retained data “0” of the SRAM cell C1 at the lower left end of the memory array A2 in the drawing can be read out.

In the block circuit diagram of FIG. 11, data can be selectively read from the two columns of SRAM cells to one global read-bit line GRBL (GRBL_2).

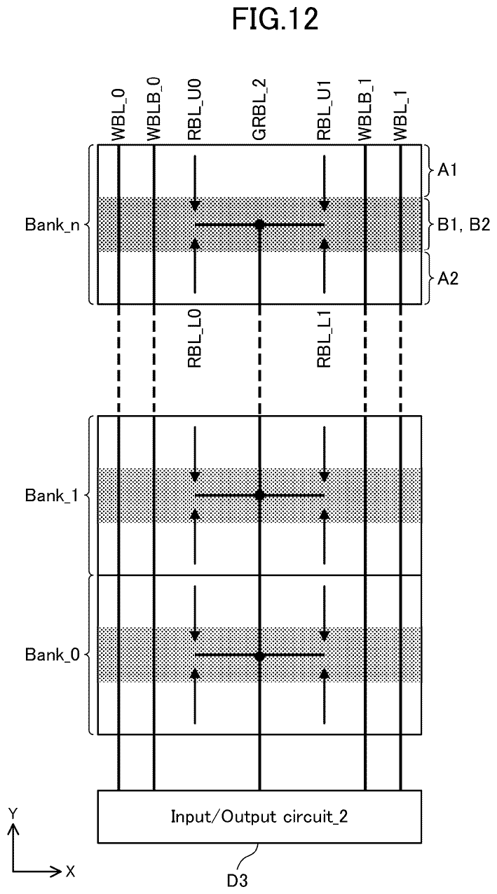

FIG. 12 is a block circuit diagram showing the whole memory array in a semiconductor storage device of the fourth embodiment. When compared with FIG. 2, FIG. 12 shows a semiconductor storage device including one global read-bit line GRBL (GRBL_2) and one input/output circuit D3. The global read-bit line GRBL_2 is connected to the input/output circuit D3. Each of the banks Bank_0 to Bank_n of FIG. 12 includes the block circuit shown in FIG. 11. The input/output circuit D3 includes a writing circuit, a reading circuit, and a global read-bit line pre-charge circuit, as in the input/output circuits D1, D2 of FIG. 2.

In the block circuit diagram of FIG. 12, one global read-bit line GRBL (GRBL_2) is formed for two columns of the SRAM cells C1. Therefore, in FIG. 12, one bit of data can be selectively read out from the two columns of SRAM cell C1 through the global read-bit line GRBL (GRBL_2).

### (Layout Structure of SRAM Cell)

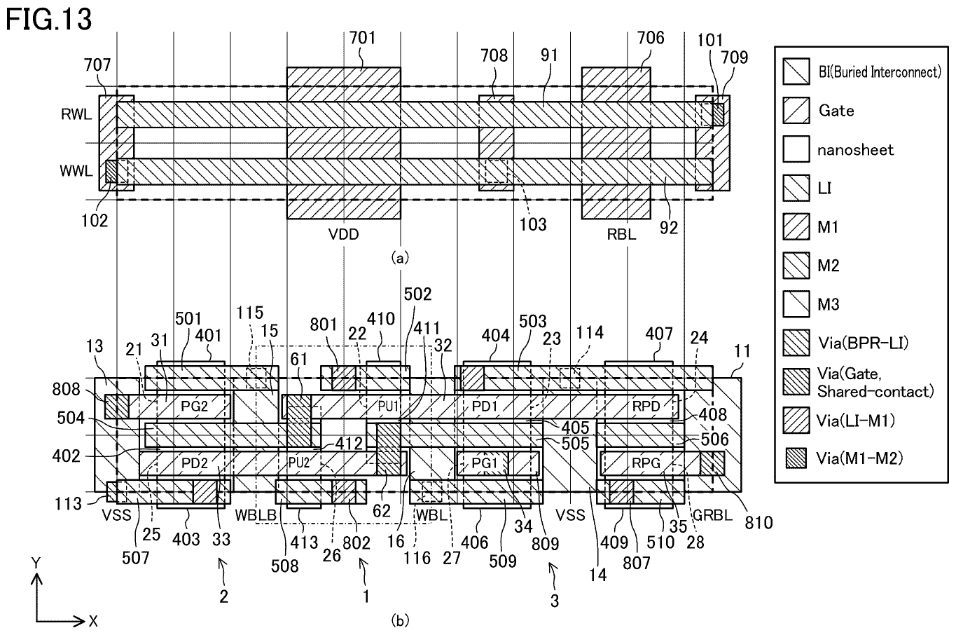

In FIG. 13, (a) and (b) are plan views of another exemplary layout structure of the 2-port SRAM cell of the fourth embodiment. Specifically, in FIG. 13, (a) shows the cell upper portion, and (b) shows the cell lower portion. When compared with FIG. 3, FIG. 13 shows a case where the interconnects 702 to 705 of the M1 interconnect layer are omitted, and the buried power rails 13, 14 and the buried interconnects 15, 16 are formed in the buried interconnect layer. Further, the arrangement of the buried interconnect 11 is different.

As shown in (b) in FIG. 13, the buried power rail 13, 14 and the buried interconnects 11, 15, 16 extending in the Y-direction are formed in the buried interconnect layer. The buried interconnect 11 is formed at the cell boundary at the right end of the cell in the drawing, and is shared with the 2-port SRAM cell arranged on the right side of the 2-port SRAM cell in the drawing.

With the layout structure of FIG. 13, the block circuits of FIGS. 11 and 12 can be formed, because the buried interconnect 11 is shared with the 2-port SRAM cell arranged on the right side of the 2-port SRAM cell in the drawing.

In addition, the number of global read-bit lines GRBLs can be reduced because one global read-bit line GRBL can be shared by two columns of the SRAM cells arranged in the X-direction. Further, reduction in the global read-bit line GRBL area allows an increase in the interconnect width of the other signal lines, thus achieving a lower resistance, consequently allowing a high speed operation of the semiconductor storage device. Further, reduction in the global read-bit line GRBL area allows an increase in the interconnect width of the other power lines, thus achieving a lower resistance, consequently allowing a stable operation of the semiconductor storage device.

Further, since the global read-bit line GRBL is a long interconnect, the parasitic capacitance of the interconnect is large. When the global read-bit line is provided for each SRAM cell column and output data is selected from two global read-bit lines by the input/output circuit, power consumption increases due to a charge/discharge current to/from the SRAM cell not subjected to data reading. In this regard, the present embodiment on the other hand requires only one global read-bit line GRBL from which data is selectively read out, thus enabling reduction in the power consumption of the semiconductor storage device.

Further, since the interconnect capacitance of the global read-bit line can be reduced, the read speed of the semiconductor storage device can be improved.

In FIGS. 11 and 12, two more columns of SRAM cells may be added to the memory arrays A1, A2. In this case, four columns of SRAM cells share one global read-bit line GRBL. Further, the column selection signal LCAD may be set to 4 bits (only one of the bits is set to the high level), and the data of one column of SRAM cells C1 selected from the four columns of SRAM cells C1 may be read out.

### Variations

### (Structure in Block Circuit Diagram)

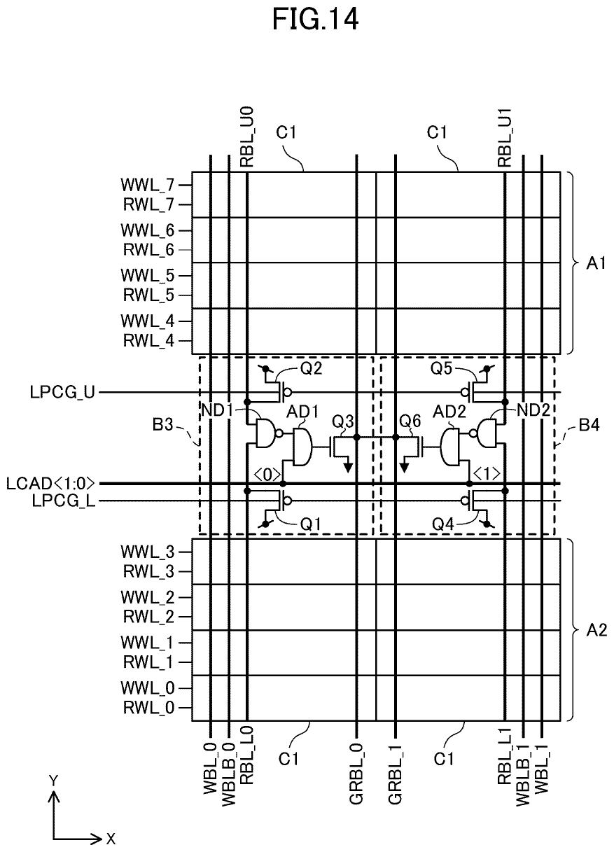

FIG. 14 is a block circuit diagram showing a part of a memory array in a semiconductor storage device of a variation of the fourth embodiment. When compared with FIG. 11, FIG. 14 shows a case where two global read-bit lines GRBL_0, GRBL_1 are formed and connected to the transistors Q3, Q6, respectively. The global read-bit lines GRBL_0, GRBL_1 are connected to each other.

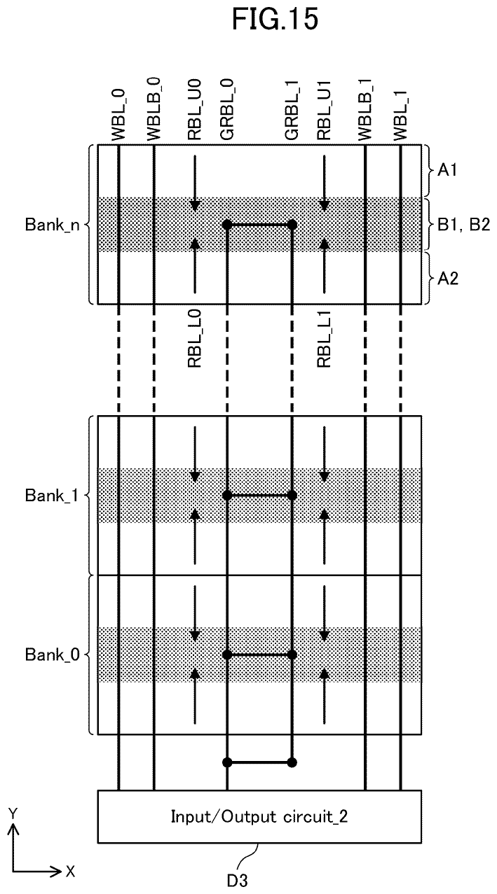

FIG. 15 is a block circuit diagram showing the whole memory array in a semiconductor storage device of a variation of the fourth embodiment. When compared with FIG. 12, FIG. 15 shows a semiconductor storage device including two global read-bit lines GRBL_0, GRBL_1 and one input/output circuit D3. The global read-bit lines GRBL_0, GRBL_1 are connected to the input/output circuit D3.

In this variation, since the two global read-bit lines GRBL are connected in parallel to the transistors Q3, Q6, the resistances of the global read-bit lines GRBL_0 and GRBL_1 can be reduced and the semiconductor storage device can operate at a high speed.

In addition, advantages similar to those of FIGS. 11 and 12 can be obtained.

The 2-port SRAM cell shown in FIGS. 3, 8, 9, 10, 16, 18, and 19 can be applied to the SRAM cell C1 in FIGS. 14 and 15.

### Fifth Embodiment

### (Layout Structure of SRAM Cell)

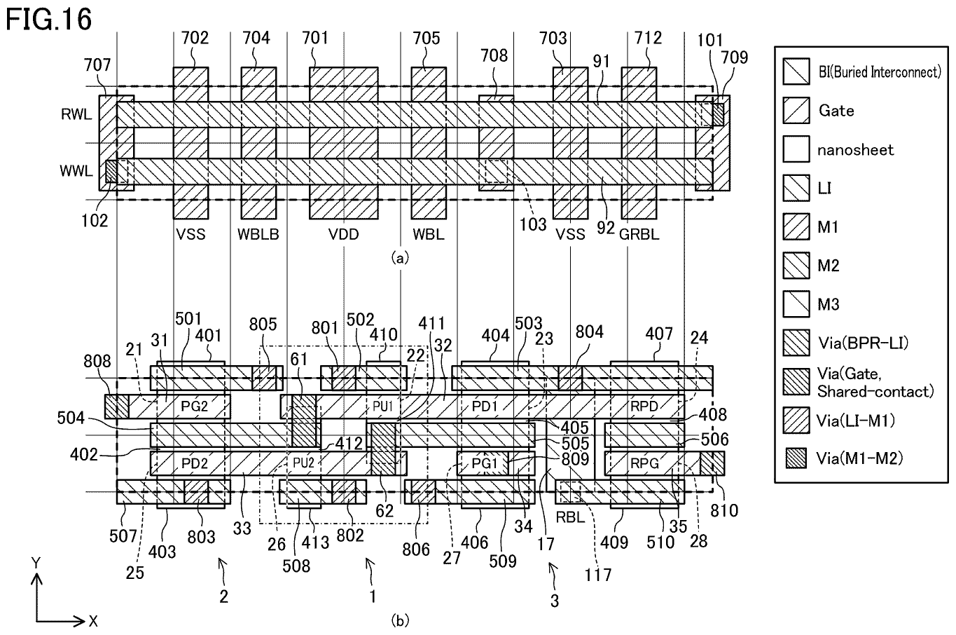

In FIG. 16, (a) and (b) are plan views of an exemplary layout structure of a 2-port SRAM cell according to the fifth embodiment. Specifically, in FIG. 16, (a) shows a cell upper portion, and (b) shows a cell lower portion. When compared with FIG. 3, FIG. 15 shows the M1 interconnect layer including an interconnect 712 instead of the interconnect 706 and the buried interconnect layer including a buried interconnect 17 instead of the buried interconnect 11.

As shown in (b) in FIG. 16, the buried interconnect 17 extending in the Y-direction is formed in the buried interconnect layer, spanning both upper and lower ends of the cell. The buried interconnect 17 corresponds to the local read-bit line RBL. The buried interconnect 17 is connected to the local interconnect 510 through a contact 117.

As shown in (a) in FIG. 16, in the M1 interconnect layer, interconnects 701 to 705, 712 extending in the Y-direction are formed, spanning both the upper and the lower ends of the cell in the drawing. The interconnect 701 supplies the power supply voltage VDD. The interconnects 702, 703 supply the power supply voltage VSS. The interconnects 704, 705 correspond to the write-bit lines WBLB, WBL, respectively. The interconnect 712 corresponds to the global read-bit line GRBL. The interconnect 712 is not connected to another interconnect or the like in the SRAM cell, but is connected to the local amplifier B1 (B2) in the bank as described above. The interconnect 712 does not have to be formed in advance. An interconnect area may be provided in advance and the buried interconnect 712 may be formed only in a necessary area when designing semiconductor storage devices.

With the above configuration, memory arrays A1, A2 include multiple SRAM cells C1 (2-port SRAM cells) arranged in the X-direction and Y-direction, respectively. The SRAM cells C1 are commonly connected to the write-bit lines WBL, WBLB extending in the Y-direction and the local read-bit line RBL extending in the Y-direction. The local read-bit line RBL is connected to the local amplifier B1 (B2). The local amplifier B1 (B2) outputs the signal received from the selected SRAM cell C1 through the local read-bit line RBL to the global read-bit line GRBL. The interconnect 712 corresponding to the global read-bit line GRBL is formed in the M1 interconnect layer. The buried interconnect 17 corresponding to the local read-bit line RBL is formed in the buried interconnect layer.

That is, since the buried interconnect 17 corresponding to the local read-bit line RBL is formed in the buried interconnect layer, there is no need for providing an interconnect corresponding to the local read-bit line RBL in the M1 interconnect layer. This suppresses an increase in the area of the semiconductor storage device.

When the interconnect resistance of the buried interconnect layer is high because the sheet resistance of the buried interconnect layer is high and the interconnect thickness cannot be increased, forming local read-bit lines RBL with a shorter interconnect length than that of the global read-bit lines GRBL in the buried interconnect layer can suppress the reduction in the operation speed of the semiconductor storage device.

The interconnect 701 of the M1 interconnect layer may be omitted, and a buried power rail that supplies the power supply voltage VDD to the buried interconnect layer may be formed. Further, the interconnects 702, 703 of the M1 interconnect layer may be omitted, and a buried power rail that supplies the power supply voltage VSS to the buried interconnect layer may be formed. In this case, the buried power rail that supplies the power supply voltage VSS may be arranged at the cell boundaries at both left and right ends of the SRAM cell in the drawing. In addition, if some or all of the interconnects 701 to 703 of the M1 interconnect layer are omitted, the interconnect widths of the interconnects 704, 705, 712 may be widened.

### (Layout Structure of Local Amplifier)

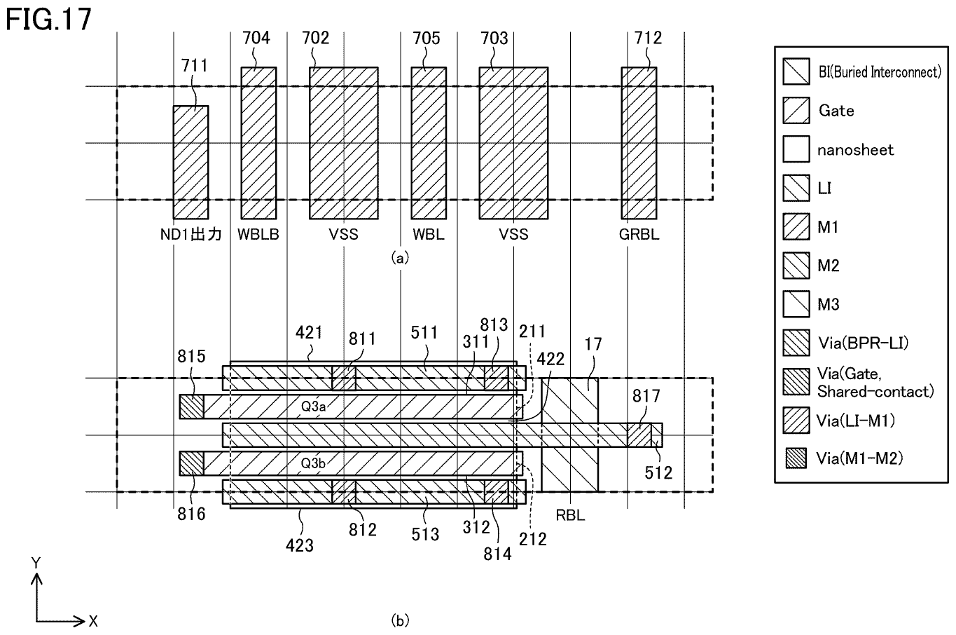

In FIG. 17, (a) and (b) are plan views of an exemplary layout structure of a driver of a global read-bit line in a local amplifier of the first embodiment. Specifically, in FIG. 17, (a) shows an upper portion of the driver, and (b) shows a lower portion of the driver. When compared with FIG. 7, FIG. 17 shows the M1 interconnect layer including an interconnect 712 instead of the interconnect 706, and the buried interconnect layer including a buried interconnect 17 instead of the buried interconnect 11.

As shown in (b) in FIG. 17, the buried interconnect 17 (local read-bit line RBL) extending in the Y-direction, spanning both the upper and the lower ends of the drawing is formed in the buried interconnect layer.

As shown in (a) in FIG. 17, in the M1 interconnect layer, the interconnects 702 to 705, 712 extending in the Y-direction are formed, spanning both the upper and the lower ends of the drawing. Further, an interconnect 711 is formed. The interconnect 711 is an interconnect connected to the output of the NAND circuit ND1.

As shown in (a) in FIG. 17, interconnects 704, 705 corresponding to the write-bit lines WBLB, WBL, respectively, are formed in the M1 interconnect layer. The interconnects 704, 705 are not connected to other interconnects in the local amplifier B1 (B2), but are connected to the interconnects 704, 705 in the SRAM cell C1 (SRAM cell in FIG. 17 or the like), respectively.

The interconnect 712 corresponding to the global read-bit line GRBL is formed in the M1 interconnect layer. The interconnect 712 is connected to the transistor Q3 (Q3a, Q3b) in the local amplifier through the local interconnect 512 and the contact 817, and is connected to the interconnect 712 in the SRAM cell C1. That is, the interconnect 713 is connected to the transistor Q3 without going through the buried interconnect layer. This allows reduction in the resistance of the global read-bit line GRBL, and allows a high speed operation of the semiconductor storage device.

### Variation 1

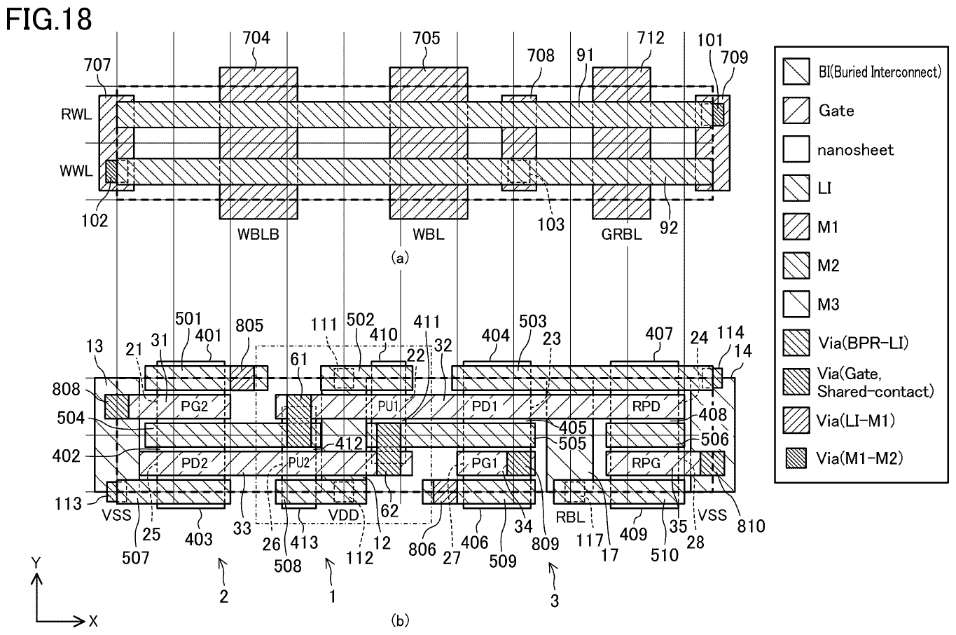

In FIG. 18, (a) and (b) are plan views of another exemplary layout structure of a 2-port SRAM cell according to the fifth embodiment. Specifically, in FIG. 18, (a) shows a cell upper portion, and (b) shows a cell lower portion. When compared with FIG. 16, FIG. 18 shows a case where the interconnects 701 to 703 of the M1 interconnect layer are omitted, and the buried power rails 12 to 14 are formed in the buried interconnect layer.

As shown in (b) in FIG. 18, the buried power rails 12 to 14 extending in the Y-direction are formed in the buried interconnect layer, spanning both the upper and the lower ends of the cell in the drawing. The buried power rail 12 supplies a power supply voltage VDD. The buried power rails 13, 14 supply a power supply voltage VSS. The buried power rail 12 is formed at the center of the cell in the drawing. The buried power rail 13, 14 is formed at each of cell boundaries at both left and right ends of the cell in the drawing. The buried power rails 13, 14 are shared with 2-port SRAM cells arranged on the left and right sides of the 2-port SRAM cell in the drawing.

As shown in (a) in FIG. 18, in the M1 interconnect layer, interconnects 704, 705, 712 extending in the Y-direction are formed, spanning both the upper and the lower ends of the cell in the drawing. The interconnects 704, 705 have interconnect width greater than that of buried interconnect 17 and those of the buried power rails 12 to 14 in plan view, respectively.

In this variation, since the buried power rail 12 that supplies the power supply voltage VDD and the buried power rails 13, 14 that supply the power supply voltage VSS are formed in the buried interconnect layer, the interconnect width of the interconnects 704, 705 corresponding to the respective write-bit lines WBLB, WBL can be increased. This makes it possible to improve the write characteristics of the semiconductor storage device, such as a higher speed and a lower voltage. Further, since the interconnect width of the interconnect 712 corresponding to the global read-bit line GRBL can be increased, the resistance of the global read-bit line GRBL can be reduced, and the read characteristics of the semiconductor storage device can be improved.

Further, since the buried power rail 12 that supplies the power supply voltage VDD and the buried power rails 13, 14 that supply the power supply voltage VSS are formed in the buried interconnect layer, the degree of freedom in designing the M1 interconnect layer is improved.

In FIG. 18, the buried power rail 12 that supplies the power supply voltage VDD and the buried power rails 13 and 14 that supply the power supply voltage VSS are formed in the buried interconnect layer, but the present invention is not limited to this, and a part of the buried power rails 12 to 14 may be formed in the M1 interconnect layer.

### Variation 2

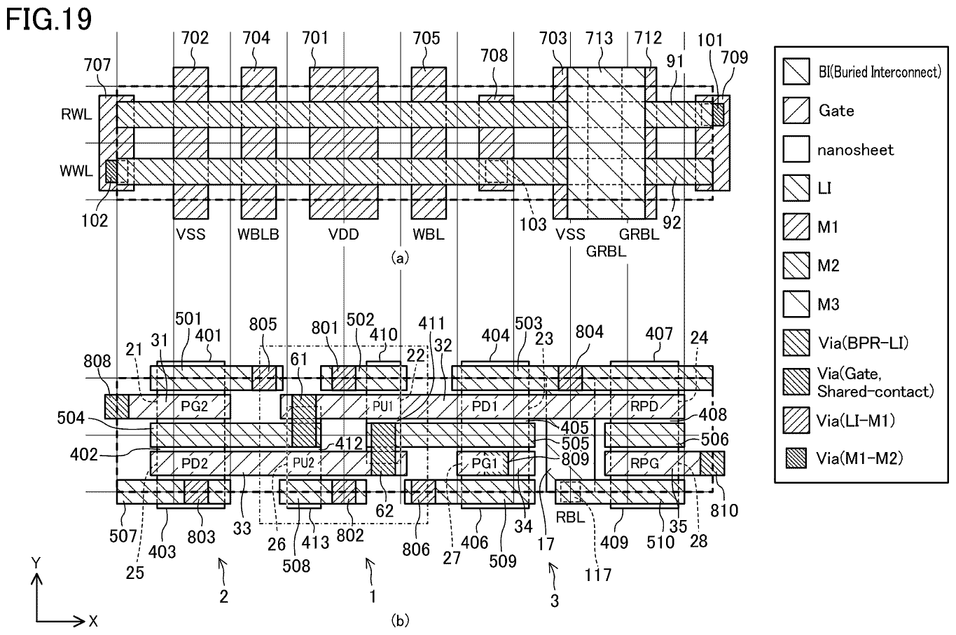

In FIG. 19, (a) and (b) are plan views of another exemplary layout structure of a 2-port SRAM cell according to the fifth embodiment. Specifically, in FIG. 19, (a) shows a cell upper portion, and (b) shows a cell lower portion. When compared with FIG. 16, FIG. 19 shows a case where the interconnect 713 is formed in the M3 interconnect layer above the M2 interconnect layer.

As shown in (a) in FIG. 19, in the M3 interconnect layer above the M2 interconnect layer, interconnect 713 extending in the Y-direction is formed, spanning both the upper and the lower ends of the cell in the drawing. The interconnect 713 corresponds to the global read-bit line GRBL. The interconnect 713 is not connected to another interconnect or the like in the SRAM cell, but is connected to the local amplifier B1 (B2) in the bank as described above. The interconnect 713 does not have to be formed in advance. An interconnect area may be provided in advance and the buried interconnect 713 may be formed only in a necessary area when designing semiconductor storage devices.

In this variation, the global read-bit line GRBL includes an interconnect 712 formed in the M1 interconnect layer and an interconnect 713 formed in the M3 interconnect layer. That is, two global read-bit lines GRBL are formed in the SRAM cell. This way, the resistance of the global read-bit line GRBL can be lowered, and the semiconductor storage device can operate at a high speed.

Note that, since no other interconnect is arranged near the interconnect 713, the degree of freedom in the interconnect width is high. The global read-bit line GRBL may be only the interconnect 713 in the M3 interconnect layer, and an interconnect 712 in the M1 interconnect layer may be omitted in a case of relatively dense state. This enables achievement of a most preferable relationship between the interconnect capacitance and the interconnect resistance of the global read-bit line GRBL, thereby allowing a high speed operation of the semiconductor storage device.

In FIG. 19, the interconnect 701 that supplies the power supply voltage VDD and the interconnects 702, 703 that supply the power supply voltage VSS are formed in the M1 interconnect layer, but the present invention is not limited to this, and a part of the interconnects 701 to 703 may be formed in the buried interconnect layer.

### Variation 3

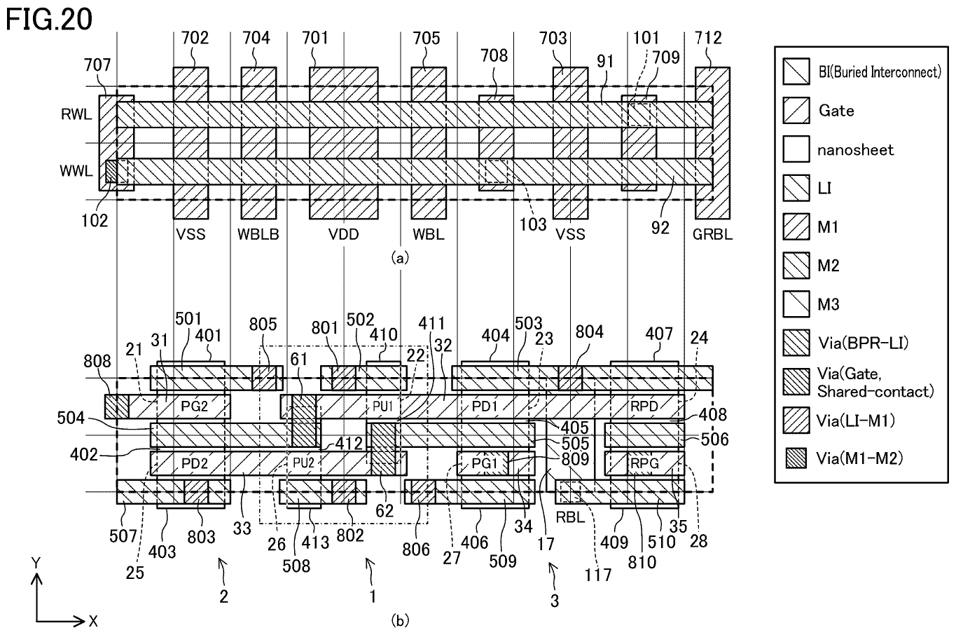

In FIG. 20, (a) and (b) are plan views of another exemplary layout structure of a 2-port SRAM cell according to the fifth embodiment. Specifically, in FIG. 20, (a) shows a cell upper portion, and (b) shows a cell lower portion. The arrangement of the interconnect 712 in FIG. 20 is different from that in FIG. 16.

As shown in (a) in FIG. 20, the interconnect 712 is formed at the cell boundary at the right end of the cell in the drawing, and is shared with the 2-port SRAM cell arranged on the right side of the 2-port SRAM cell in the drawing. Thus, the block circuits of FIGS. 11 and 12 can be achieved.

In the above embodiments and variations, each transistor includes the three nanosheets, but some or all of the transistors may include a single nanosheet, or two or four or more nanosheets.

In the above embodiments and variations, the sectional shape of the nanosheet is rectangular, but is not limited to this shape. For example, the shape may be square, circular, or elliptical.

In the above embodiments and variations, the shared-contacts 61, 62 may be manufactured in the same process as that for the contact (Gate-Contact) and the local interconnect, or may be manufactured in a different process.

In the above embodiments and variations, the width of each of the nanosheets 21, 23, 24, 25, 27, 28 in the X-direction is twice the width of each of the nanosheets 22, 26 in the X-direction, but is not limited to this width. The width of each of the nanosheets 21 to 28 (i.e., the gate width of each transistor) in the X-direction may be determined in consideration of the operational stability of the 2-port SRAM circuit.

In the above embodiments and variations, the 2-port SRAM cell shown in FIGS. 3, 8, 9, 10, 16, 18, and 19 can be applied to the SRAM cell C1 in FIGS. 1 and 2. The 2-port SRAM cell shown in FIGS. 13 and 20 can be applied to the SRAM cell C1 in FIGS. 11 and 12. The 2-port SRAM cell shown in FIGS. 3, 8, 9, 10, 16, 18, and 19 can be applied to the SRAM cell C1 in FIGS. 14 and 15.

In the above embodiments and variations, the case where the transistor disposed in the 2-port SRAM cell is the nanosheet FET has been described as an example. However, the present invention is not limited thereto, and the transistor disposed in the 2-port SRAM cell may be a FinFET.

In the above embodiments and variations, the P-type substrates 2, 3 may be P-wells.

With the present disclosure, a semiconductor storage device including a 2-port SRAM cell in which a bit line is provided in a buried interconnect layer can be achieved.

What is claimed is:

1. A semiconductor storage device including multiple memory arrays,
the memory arrays each including multiple 2-port SRAM cells arranged in a first direction,
the 2-port SRAM cells in each of the memory arrays being commonly connected to a first write-bit line extending in the first direction, a second write-bit line extending in the first direction and forming a complementary bit line pair together with the first write-bit line, and a local read-bit line extending in the first direction,
the local read-bit line being connected to a local amplifier,
the local amplifier being configured to output a signal received from selected one or more of the 2-port SRAM cells to a global read-bit line through the local read-bit line,
the global read-bit line including a first buried interconnect formed in a buried interconnect layer and extending in the first direction in the memory arrays,
the local read-bit line including a first interconnect formed in a first interconnect layer above the buried interconnect layer and extending in the first direction.

2. The semiconductor storage device of claim 1, wherein
the first interconnect is connected to the local amplifier outside an area where the memory arrays are arranged.

3. The semiconductor storage device of claim 1, wherein
the 2-port SRAM cell includes:
a second interconnect formed in the first interconnect layer, connected to a first power source that supplies a first voltage, and extending in the first direction; and
a third interconnect formed in the first interconnect layer, connected to a second power source that supplies a second voltage different from the first voltage, and extending in the first direction.

4. The semiconductor storage device of claim 1, wherein
the 2-port SRAM cell includes:
a first buried power rail formed in the buried interconnect layer, connected to the first power source that supplies the first voltage, and extending in the first direction.

5. The semiconductor storage device of claim 4, wherein
the first buried power rail is arranged at a boundary between the 2-port SRAM cells adjacent to each other in a second direction perpendicular to the first direction.

6. The semiconductor storage device of claim 4, wherein
the 2-port SRAM cell includes:
a second buried power rail formed in the buried interconnect layer, connected to a second power source that supplies a second voltage different from the first voltage, and extending in the first direction.

7. The semiconductor storage device of claim 6, wherein
the first write-bit line includes a second interconnect formed in the first interconnect layer and extending in the first direction,
the second write-bit line includes a third interconnect formed in the first interconnect layer and extending in the first direction, and
the second and third interconnects each have an interconnect width greater than that of each of the first and second buried power rails and the first buried interconnect in a plan view.

8. The semiconductor storage device of claim 4, wherein
the 2-port SRAM cell includes:
a second interconnect formed in the first interconnect layer, connected to a second power source that supplies a second voltage different from the first voltage, and extending in the first direction,
the first write-bit line includes a second buried interconnect formed in the buried interconnect layer and extending in the first direction,
the second write-bit line includes a third buried interconnect formed in the buried interconnect layer and extending in the first direction, and
the second interconnect has an interconnect width greater than that of the first to third buried interconnects and the first buried power rail in a plan view.

9. The semiconductor storage device of claim 8, wherein
the global read-bit line includes a third interconnect formed in the first interconnect layer and extending in the first direction.

10. A semiconductor storage device including multiple memory arrays,
the memory arrays each including multiple 2-port SRAM cells arranged side by side in a first direction and in a second direction that is perpendicular to the first direction,
the 2-port SRAM cells in each of the memory arrays being commonly connected to a first write-bit line extending in the first direction, a second write-bit line extending in the first direction and forming a complementary bit line pair together with the first write-bit line, and a local read-bit line extending in the first direction,
the local read-bit line being connected to a local amplifier,
the local amplifier being configured to output a signal received from selected one or more of the 2-port SRAM cells to a global read-bit line through the local read-bit line,
the global read-bit line including a first buried interconnect formed in a buried interconnect layer, arranged at the boundaries of the SRAM cells arranged in the second direction in the memory arrays, and extending in the first direction.

11. A semiconductor storage device including multiple memory arrays,
the memory arrays each including multiple 2-port SRAM cells arranged in a first direction,
the 2-port SRAM cells in each of the memory arrays being commonly connected to a first write-bit line extending in the first direction, a second write-bit line extending in the first direction and forming a complementary bit line pair together with the first write-bit line, and a local read-bit line extending in the first direction,
the local read-bit line being connected to a local amplifier,
the local amplifier being configured to output a signal received from selected one or more of the 2-port SRAM cells to a global read-bit line through the local read-bit line,
the local read-bit line including a first buried interconnect formed in a buried interconnect layer and extending in a first direction,
the global read-bit line including a first interconnect formed in a first interconnect layer above the buried interconnect layer and extending in the first direction in the memory arrays.

12. The semiconductor storage device of claim 11, wherein
the first interconnect is connected to the local amplifier outside an area where the memory arrays are arranged.

13. The semiconductor storage device of claim 11, wherein
the 2-port SRAM cell includes:
a second interconnect formed in the first interconnect layer, connected to a first power source that supplies a first voltage, and extending in the first direction; and
a third interconnect formed in the first interconnect layer, connected to a second power source that supplies a second voltage different from the first voltage, and extending in the first direction.

14. The semiconductor storage device of claim 13, wherein
the global read-bit line includes a fourth interconnect formed in a second interconnect layer above the first interconnect layer and extending in the first direction.

15. The semiconductor storage device of claim 11, wherein
the 2-port SRAM cell includes:
a first buried power rail formed in the buried interconnect layer, connected to a first power source that supplies a first voltage, and extending in the first direction; and
a second buried power rail formed in the buried interconnect layer, connected to a second power source that supplies a second voltage different from the first voltage, and extending in the first direction,
the first write-bit line includes a second interconnect formed in the first interconnect layer and extending in the first direction,
the second write-bit line includes a third interconnect formed in the first interconnect layer and extending in the first direction, and
the first and second interconnects each have an interconnect width greater than that of the first buried interconnect and the first and second buried power rails in a plan view.

16. A semiconductor storage device including multiple memory arrays,
the memory arrays each including multiple 2-port SRAM cells arranged side by side in a first direction and in a second direction that is perpendicular to the first direction,
the 2-port SRAM cells in each of the memory arrays being commonly connected to a first write-bit line extending in the first direction, a second write-bit line extending in the first direction and forming a complementary bit line pair together with the first write-bit line, and a local read-bit line extending in the first direction,
the local read-bit line being formed in a buried interconnect layer and is connected to a local amplifier,
the local amplifier being configured to output a signal received from selected one or more of the 2-port SRAM cells to a global read-bit line through the local read-bit line,
the global read-bit line being formed in a first interconnect layer above the buried interconnect layer and extends in the first direction to be arranged at the boundaries of the SRAM cells arranged in the second direction in the plurality of memory arrays.
